(19) United States
(12) Patent Application Publication
(10) Pub. No.: US 2025/0216464 A1
(43) Pub. Date: Jul. 3, 2025

(54) AUTOMATED BATTERY HEALTH ASSESSMENT

(71) Applicant: Universe Energy, Inc., El Segundo, CA (US)

(72) Inventors: Wiebe Janssen, Venice, CA (US); Raymond Ruoqin Ma, Gardena, CA (US)

(21) Appl. No.: 19/003,530

(22) Filed: Dec. 27, 2024

Related U.S. Application Data
(60) Provisional application No. 63/616,415, filed on Dec. 29, 2023.

(51) Int. Cl. G01R 31/367; G01R 31/392

(52) U.S. Cl. CPC G01R 31/367; G01R 31/392

(57) ABSTRACT

The state of health (SOH) and remaining useful life (RUL) of a secondary battery, at the end of the first life cycle of the battery, are relevant parameters to deciding an efficient pathway for remanufacturing, repurposing, or recycling of the battery. Robotic agents, coupled with non-intrusive sensors, can perform SOH and/or RUL assessment. Robotic agents can accept motion trajectories to move the sensors to selected positions on a battery. The sensors can scan a battery, or a portion of the battery. The sensor readings can be correlated to SOH and/or RUL parameters. Artificial intelligence models can be trained with used batteries having known defects. The trained models can detect patterns, indicative of cell failure. The models can also be trained to detect failure sites. Non-intrusive tests can be performed more efficiently by scanning only a selection of the cells, in or near the failure sites.

### CROSS-REFERENCE TO RELATED APPLICATIONS

This application claims the benefit of priority to U.S. Provisional Application No. 63/616,415, filed on Dec. 29, 2023, titled “AUTOMATED BATTERY HEALTH ASSESSMENT,” which is hereby incorporated by reference in its entirety.

### BACKGROUND

### Field

This invention relates generally to the field of secondary storage devices and robotics, and more particularly, to systems and methods for robotic disassembly of secondary storage devices and robotic health assessment and prediction for secondary batteries.

### Description of the Related Art

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

Secondary batteries contain valuable resources and material that can be recycled and reused in a variety of ways. The secondary batteries, used in electrical vehicles (EVs) and hybrid electrical vehicles (HEV), can be recycled and reassembled into the same or similar EV or HEV batteries, used as grid storage devices, or turned back into raw material for use in batteries or other applications. Depending on the state of health (SOH) of a battery, a particular reuse or recycle strategy for the battery can be implemented. Sometimes a portion of a battery can be reused in a rather demanding application if that portion is relatively free of degradation, while another battery portion is recycled or reused in less demanding applications. Consequently, disassembly and state of health analysis are important steps in the life cycle of secondary batteries.

Manual disassembly of secondary batteries can be performed. Often trained technicians, observing stringent safety protocols perform the manual disassembly. Acquiring the necessary training can be challenging. Several variations of secondary batteries exist, some without easily accessible manufacturer disassembly instructions, or battery architectural diagrams. Consequently, it can be difficult for human technicians to accumulate the necessary knowledge and disassembly know-how for the disparate battery types.

Furthermore, in many prevalent applications of secondary batteries, such as in EV and HEV applications, technicians are potentially exposed to high voltages and currents, making the task, particularly, dangerous to humans. The task is made more dangerous, as in many battery types, clean disassembly may not have been envisioned by the manufacturers. Some steps in the disassembly can be destructive, for example, requiring detaching battery portions that are glued, or welded, as opposed to being fastened using fasteners, screws or bolts. Performing destructive disassembly, as may be required for several battery types, can be particularly, perilous to human technicians.

To reduce the risk of electrocution, batteries can be discharged before disassembly. However, assessing the state of health of a battery may require the batteries and the battery cells to be charged. Many methods of assessing state of health of batteries perform power cycling on battery cells, using one or more onboard battery management systems (BMS) that are only usually accessible, when at least some disassembly is performed to gain access the to the BMS modules. In addition, charging and discharging the battery cells to accommodate both the human safety protocols and to perform SOH analysis can be time-consuming, making the disassembly slow and less economical to perform. For example, in some cases, charging and discharging an EV or HEV battery can take in excess of 30 hours.

Some battery disassembly tasks also require dexterity, while safety requires the human technicians to wear protective gear, making the performance of such tasks challenging, or more time-consuming.

These and other challenges of the manual disassembly of secondary batteries can be addressed by performing the assembly, autonomously, or semi-autonomously, using robotic technology. Additionally, autonomous, or semi-autonomous battery disassembly can confer several benefits that would not otherwise be available with manual disassembly processes. Several of these benefits can become evident in relation to the described embodiments.

Another aspect of interest to secondary battery industry is utilizing state of health assessment techniques to aid in deciding a recycling strategy for a used secondary battery. Knowing the present state of health of a battery and an ability to predict its future state of health, or the battery's remaining useful life, can inform the secondary life destination of the battery. Some secondary batteries include hundreds of modules and sometimes thousands of cells. If the battery has many health cells, a repair, or cell replacement can be an economically- and environmentally-sound secondary life destination for the battery. If many cells are degraded or damaged, recycling to raw material, may be a better secondary life destination for the battery, as opposed to disassembly. Some existing methods of state of health assessment rely on performing charging and discharging cycles and measuring various electrical parameters. Other assessment methods utilize purpose-built chambers that in some cases cannot physically accommodate large secondary batteries, for example, those used in EVs or HEVs. Some traditional battery health assessment methodologies, for example, the ones using charging and discharging, can be extremely time-consuming. Consequently, there is a need for improved battery health assessment techniques that can process a substantial number of secondary batteries in an efficient and accurate manner.

### SUMMARY

The appended claims may serve as a summary of this application.

### BRIEF DESCRIPTION OF THE DRAWINGS

These drawings and the associated description herein are provided to illustrate specific embodiments of the invention and are not intended to be limiting.

FIG. 1 illustrates a block diagram of an automated battery disassembly system (ABDS) according to an embodiment.

FIG. 2 illustrates a diagram of an automated battery disassembly strategy, implemented in one or more embodiments.

FIG. 3 illustrates a flowchart of an example method of autonomous battery disassembly.

FIG. 4 illustrates a block diagram of software modules of an example ABDS in one embodiment.

FIG. 5 illustrates a diagram of an alternative implementation of the software architecture of the ABDS.

FIG. 6 illustrates a block diagram of an overview of example sources and techniques for generating a task primitive dataset.

FIG. 7 illustrates a block diagram of some example components, used in generating an estimation of a tool state, which can be used to generate instruction sources for manual and/or automated battery disassembly.

FIG. 8 illustrates a block diagram of example process steps for generating robotic task primitives, from manual battery disassembly processes.

FIG. 9 is a block diagram of an example of the operations of a task planner, when modifying a reference task primitive.

FIG. 10 illustrates an environment in which some embodiments may operate.

FIG. 11 illustrates a diagram of an embodiment utilizing non-intrusive testing to determine state of health and remaining useful life of a battery.

FIG. 12 illustrates a diagram of a battery identification system, which can be used in the embodiments of non-intrusive testing.

FIG. 13 illustrates a diagram of a non-intrusive battery assessment system (NBAS), according to an embodiment.

FIG. 14 is a diagram of an example implementation of an NBAS, according to one embodiment.

FIG. 15 is a flowchart of an example method of operations of a non-intrusive battery assessment system, according to an embodiment.

FIG. 16 illustrates a flowchart of an example method of performing battery health assessment, using a selection of the cells of a battery.

FIG. 17 illustrates a flowchart of an example method, for using high-fidelity battery assessment to obtain parameters for performing low-fidelity assessment.

FIGS. 18 and 19 illustrate flowcharts of example methods for building one or more state of health and remaining useful life prediction models.

### DETAILED DESCRIPTION

The following detailed description of certain embodiments presents various descriptions of specific embodiments of the invention. However, the invention can be embodied in a multitude of different ways as defined and covered by the claims. In this description, reference is made to the drawings where like reference numerals may indicate identical or functionally similar elements.

Unless defined otherwise, all terms used herein have the same meaning as are commonly understood by one of skill in the art to which this invention belongs. All patents, patent applications and publications referred to throughout the disclosure herein are incorporated by reference in their entirety. In the event that there is a plurality of definitions for a term herein, those in this section prevail. When the terms “one”, “a” or “an” are used in the disclosure, they mean “at least one” or “one or more”, unless otherwise indicated.

Many modem industries have utilized secondary batteries to deliver products and services to consumers. Electric vehicles and hybrid vehicles, in particular, have widely adopted and popularized the use of secondary batteries in modem vehicles. However, the adoption of secondary battery technologies has presented new challenges, including economical and environmental challenges. The materials used in building secondary batteries are difficult to mine and often present a substantial environmental cost to acquire and transform into secondary batteries. As such, modern manufacturers, and various industries using secondary batteries, search for ways to repair, recycle, or otherwise reuse secondary batteries, to mitigate the negative financial and environmental impact of using secondary battery technology.

Secondary batteries, such as those used in hybrid vehicles (HEVs), or electric vehicles (EVs), can find additional uses after their initial deployment, based on their state of health (SOH) after a period of use. Some secondary batteries, that are free of major damage, can be repaired, for example, by replacing damaged or worn-out cells, and reused in the same or similar function, as in their prior deployments. Not all, but various secondary battery architectures can allow for repair and redeployment of a secondary battery that has been used for some period of time in an HEV or an EV. For example, some battery architectures include modules of cells, where damaged cells, or damaged modules, can be replaced if the remaining cells or modules meet a particular use-case specification. Some secondary batteries might have a degraded state of health, but nevertheless, they can still meet operating specifications for a less demanding use case. For example, degraded, but functional secondary batteries, can find a second life as grid storage batteries. Grid storage batteries can be used in electrical distribution systems for storing electrical energy. Some secondary batteries are, however, not suitable for repurposing. These secondary batteries can be recycled to their raw materials, using various techniques, including for example, chemical separation processes. In short, a secondary battery after a reasonable lifetime of use in an application or an industry, can be repaired and reused in the same industry for the same function, or repurposed in another industry for another function, or recycled into raw materials. In order to diagnose, repair, or repurpose a secondary battery, the battery may need to be disassembled.

### Challenges of Battery Disassembly

Repairing, repurposing or recycling of a secondary battery all include at least some disassembly or may include performing diagnostics to determine which lifecycle pathway is more suitable for the state of a secondary battery. Secondary battery disassembly, particularly, in the case of large secondary batteries, such as those used in HEVs and EVs, is a demanding task, presenting substantial technical and safety challenges. For example, the disassembly of large secondary batteries can often require discharging high voltage battery cells, which can be dangerous to human technicians if not performed under stringent safety protocols. Assessing the state of health of a battery can require cycling the battery through multiple charge and discharge cycles, where each power cycle can take in excess of thirty hours to complete, when the safety protocols are observed. Additionally, numerous types and models of large secondary batteries, for which performing disassembly is economical, exist. While disassembly can include performing common tasks between different battery types, disassembly can also include substantial variations between different battery types and models. Human technicians, faced with myriad of battery types and models can be disadvantaged in battery identification and application of a correct disassembly procedure for a particular battery type.

For some secondary batteries, disassembly documentation, such as layout or disassembly manuals, can be non-existent or not easily procurable, making the battery disassembly more difficult to perform. Another disassembly challenge is that in many cases, a specific set of disassembly tasks may need to be performed, without skipping steps to ensure proper or optimum disassembly. For example, for some batteries, all wiring must be removed before attempting to remove cells and/or modules. If any wires are left, the affected cell or module can become entangled in the wires, causing damage to the cells, or presenting safety hazards. Technicians performing manual disassembly can be at a disadvantage in terms of ensuring proper disassembly tasks in the proper order have been performed. Another disassembly challenge for large secondary batteries can reside in the large size of such batteries, often requiring human technicians to utilize winches and/or heavy-duty equipment, sometimes presenting an efficiency or safety challenge for the disassembly. Consequently, the battery industry can substantially benefit from autonomous or semi-autonomous battery disassembly technology.

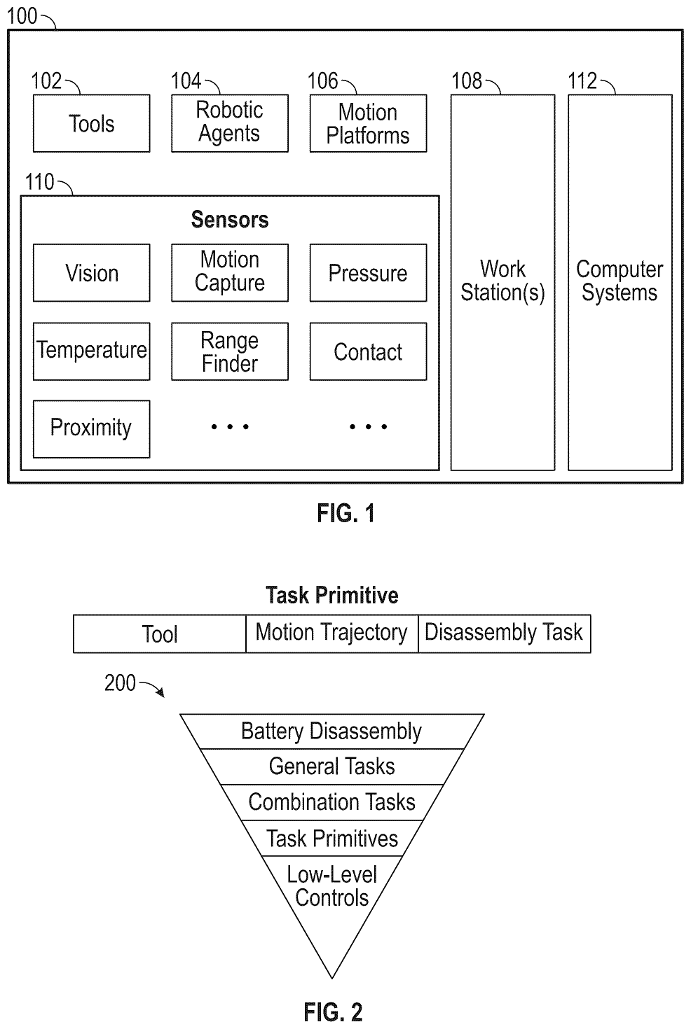

FIG. 1 illustrates a block diagram of an automated battery disassembly system (ABDS) 100 according to an embodiment. The ABDS 100 can include tools 102, which can be housed in a cache of tools. The tools 102 can be the same or similar tools to those used in manual battery disassembly. Examples include cutting tools, lifting tools, screwdriver tools, pinchers, winches, and any other tool or tool functionality that may be used in disassembly of a battery. The ABDS 100 further includes robotic agents 104. The robotic agents 104 can include both robotic and cobotic devices. Cobotic devices refer to collaborative robotic agents that perform their function with assistance from a human operator. The robotic agents 104 can include robotic arms, which can be coupled with a tool 102. The ABDS 100 can also include one or more motion platforms 106. The motion platforms 106 can move the robotic agents 104 from one location to another. Alternatively, or in addition, the motion platforms can move a battery to a tool and/or a robotic agent. The ABDS 100 can also include one or more workstations 108, which can be used to secure a battery for disassembly operations. The workstations 108 can be coupled with the robotic agents 104, and/or the motion platforms 106. In other embodiments, the workstations 108 can be independent of the robotic agents 104 and/or the motion platforms 106. Both the robotic agents 104 and workstations 108 can be stationary or mobile depending on the implementation of the ABDS 100. The ABDS 100 can also include the sensors 110. Some examples of the sensors 110 can include vision sensors, motion capture sensors, pressure sensors, temperature sensors, range finders, depth sensors, contact detection sensors, proximity sensors, accelerometers, and other sensors. One or more computer systems 112 can be used to provide software functionality for the ABDS 100.

FIG. 2 illustrates a diagram of an automated battery disassembly strategy, implemented in one or more embodiments. A battery disassembly task can be broken down into a hierarchy of progressively smaller tasks presented in the form of a funnel 200. A battery disassembly task can be broken down into a series of general battery disassembly tasks. The general battery disassembly tasks can in turn be broken down into combination tasks. Each combination task can be broken down into a series of task primitives.

### Task Primitive

Autonomous battery disassembly can be performed by a series of tool motions, performing disassembly tasks on target features on a battery, where the location, pose or state of the target feature and/or the tool are estimated or determined by querying the sensors 110, or receiving a broadcast from the sensors 110. In this context, a task primitive can include a tool, a series of motion trajectories to move the tool to a battery feature, and a disassembly task performed on the target feature. The performance of a disassembly task can include receiving a series of commands, by a robotic agent and/or a robot-augmented tool. An example of a task primitive is, “tool”=“cutting tool,” “motion trajectory is to move from position (x, y, z) to position (m, n, p),” where position (x, y, z) is where the tool is currently located, and the position (m, n, p) is where the battery feature is located, and “task performance”=“exert 5 lbs. per square inch of pressure using the cutting tool.” Some disassembly tasks include performance of two or more task primitives in parallel. In other words, task primitives can be linked in parallel, where the performance of one task primitive triggers the parallel performance of another task primitive. On the other hand, some battery disassembly tasks can include simultaneous performance of two or more task primitives in parallel. For example, cutting the external frame of some batteries may include one task primitives for one or more robotic agent arms to brace or secure the battery, or the battery frame, and for another robotic agent, armed with a cutting tool, to cut the frame.

### Low-Level Controls

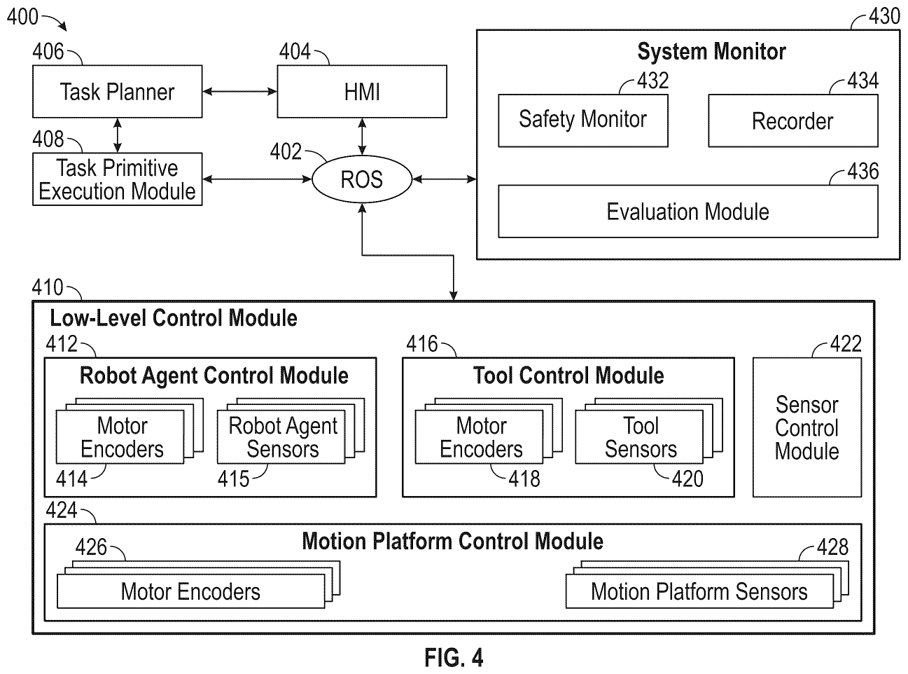

Task primitives can be translated into a series of low-level controls and commands that can be inputted into the robotic agents 104, tools 102, motion platforms 106, and/or workstations 108 to perform the task primitive. Additional details of low-level controls will be described in relation to the embodiment of FIG. 4.

### Example Method of Autonomous Battery Disassembly

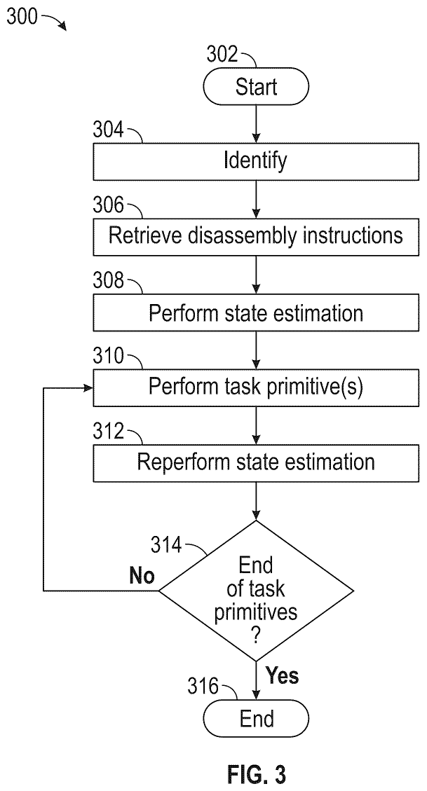

FIG. 3 illustrates a flowchart of an example method 300 of autonomous battery disassembly. The method starts at step 302. At step 304, the type of a battery can be determined. Input from various vision sensors can be used to determine the type of battery. For example, the vision sensors can scan text, labels, barcodes, or other visually identifying information to determine battery type. In some embodiments, unique or identifying features of the batteries can be used to determine battery type. For example, a unique shape of a cover lid, or a unique shape of a battery compartment can be used to identify a battery type.

At step 306, based on the identified battery type, a set of disassembly instructions can be retrieved. Disassembly instructions can include a series of task primitives to accomplish battery disassembly. At step 308, the state of the universe of the battery disassembly environment is estimated. State estimation at step 308 can include estimating the location of the battery relative to one or more robotic agents 104. Estimating, querying, or otherwise determining the location of the battery, the tools 102, one or more robotic agents 104, motion platforms 106, and one or more workstations 108, relative to one another or relative to a reference point can be a part of the state estimation performed at step 308. The location estimation can be made easier when the battery is secured in a platform with hard stops, whose locations, relative to various robotic agents 104 are known. In other words, hard stops, securing a battery in a workstation 108 can be used as reference points for the vision sensors to estimate the location of a battery and/or battery features, relative to robotic agents 104. In some embodiments, point cloud data can be used to estimate the location of a battery, relative to the robotic agents 104. Point cloud data can include data returned by red, green, blue, depth (RBGD) vision sensors. Point cloud data can include RBG data, as well as cartesian coordinates (e.g., X, Y, and Z, relative to a reference point). State estimation can also include determining success or failures of any prior task primitives that may be related to or required for the performance of a subsequent task primitive.

At step 310, one or more task primitives, from the series of task primitives, retrieved at step 306 are performed. Performing a task primitive can include selecting a tool associated with the task primitive, locating a target feature associated with the task primitive, moving the tool and/or the robotic agent to the target feature, and performing the disassembly task associated with the task primitive, by operating the tool on the target feature.

In some embodiments, selecting the tool at step 310 can include moving a robotic agent 104 to a cache of tool 102, depositing a prior active tool, and loading and/or arming the robotic agent 104 with a new tool 102, associated with a new task primitive. Locating a target feature associated with the task primitive can include querying the vision sensors, filtering noise, or outliner data, and calculating locations of the target feature and the selected tool, relative to one another, or relative to another reference point.

Moving a tool 102 to a target battery feature can include planning a collision free motion trajectory between the two, and actuating motion platforms 106, the robotic agent 104, and/or the tool 102, to execute the planned motion trajectory. In some embodiments, state estimation and/or location estimation can be reperformed, to refine the estimated locations and improve the likelihood of the tool 102 successfully moving to a target feature.

Step 310 further includes operating the selected tool on the target feature, performing the disassembly task embedded in a task primitive. Below, some examples of task primitives performed at step 310 are described.

For a task primitive directed to unscrewing a fastener, where the target feature is a fastener, selecting a tool can include swapping a prior active tool to an impact wrench with sockets matching the target fastener. Localizing the target feature can include estimating the location of the fastener relative to motion platform 106 coordinate frame. Moving to the target feature can include moving the tool armed with impact wrench to the socket above the target fastener head, parallel to the target fastener plate plane. Operating the tool can include engaging the fastener head with the socket and unscrewing the target fastener. In some cases, the tooling may have additional compliant elements to passively help engage the socket to the target fastener head.

For a task primitive directed to cutting a top lid, the target feature can be a contour cutting path on the top lid panel of the battery. Selecting a tool can include swapping from a prior active tool to an angle grinder or a cutting wheel. Localizing the target feature can include detecting the overall battery pack shape and locating a starting point of a selected contour cutting path. Moving the tool to the target feature can include moving the cutting tool to the starting point of the contour cutting path. Operating the tool can include turning the cutting tool ON and moving the cutting tool through the contour cutting path.

For a task primitive directed to de-connectorizing a harness, the target feature is the harness and the connector tabs coupled with the harness. Selecting a tool can include swapping a prior active tool to a specialized end-effector tool for de-connectorizing. Localizing the target feature can include estimating the location of the harness connector and the relevant release-tabs. Moving the tool to the target feature can include moving the tool to close proximity of a connector and orienting the tool, such that the tabs are accessible to the tool. Operating the tool can include engaging the tool with the connector tabs, depressing the tabs, and pulling the connector outwards. In this scenario, the specialized connector can be designed to depress the tabs and disengage the connector.

For a task primitive directed to moving a harness out of the workspace of another task primitive, the target feature is a grasping location on the harness, for example, near a connector of a harness. Selecting a tool can include swapping a prior active tool for a gripper tool. Localizing the target feature can include finding the harness cable and the connector at or near the grasping location on the harness. Moving the tool to the target feature can include moving the gripper tool to the grasping location on the harness near the connector. Operating the tool can include grasping the harness cable body near connector at the grasping location and moving the harness out of the workspace of another task primitive.

At step 312, state estimation, as described in relation to step 308 is reperformed, including determining whether the task primitive performed at step 310 was completed successfully. If a failure is detected, the method can return to step 310 and attempt to reperform the task primitive. Alternatively, or in addition, an alert, or an error message, can be generated. At step 314, it is determined whether the task primitives outlined in the disassembly instructions are exhausted. If yes, the method ends at step 316. If not, the method returns to step 310 to perform another task primitive. In some embodiments, after performing state estimation, a task primitive can be modified. For example, one or more motion trajectories in a task primitive and/or a tool in a task primitive may be dynamically modified, based on the result of state estimation. The modification of a task primitive, and its associated motion trajectories and/or tools can be for optimization (e.g., to use the shortest, or fastest path, or to reduce power consumption), or it may be for avoiding failures (e.g., when an obstacle in the path of a motion trajectory of a task primitive is detected).

### Methods of Generating Disassembly Instructions and Task Primitives

Battery disassembly instructions can be generated by a variety of methods. These methods can be combined, and/or used independently to generate battery disassembly instructions for a type of battery. In some embodiments, the battery disassembly instructions can be generated by obtaining original equipment manufacturer (OEM) resources. For example, some OEMs publish disassembly manuals, diagrams, component lists, or other specification documents that can directly or indirectly be used in generating battery disassembly instructions. Another method of generating battery disassembly instructions include simulation, using software models. In other embodiments, disassembly instructions can be manually generated, for example, by generating rule-based commands, where tool selection, and Cartesians motions are inputted into motion platforms 106 and/or robotic agents 104 in the form of a series of inputs to simulate a known battery disassembly task. If the simulation is successful, for example, in accomplishing a disassembly task, the series of inputs and the Cartesians motions are retained to generate battery disassembly instructions and/or the underlying task primitives.

Another method of generating battery disassembly instructions can include attaching tracking sensors, such as motion capture sensor, pressure sensor, and/or other sensors to a tool, or a technician's hands, arms and/or body to record the technician's performance of a disassembly task. The output of the tracking sensors can be recorded and used to generate battery disassembly instructions, and/or the underlying task primitives.

The methods of generating battery disassembly instructions and/or task primitives described above can be updated over time and refined based on the outcome of the performance of previous battery disassembly tasks. For example, the output of state estimation can be used to tune the disassembly instructions, and/or the task primitives.

### Software Architecture

An ABDS can include a variety of disparate hardware and software systems, obtained from third-party vendors, and/or developed natively in the environment of ABDS. In some embodiments, a robotic operating system (ROS) can act as the interface and communication portal between disparate system parts.

FIG. 4 illustrates a block diagram 400 of software modules of an example ABDS in one embodiment. Various components may be natively developed in the environment of the ABDS or obtained from third-party vendors. The ROS 402 can provide a common interface and communication endpoint between the components. A human technician operator can interface with the ABDS via a human machine interface (HMI) 404. The HMI 404 can include one or more graphical user interfaces (GUIs). A task planner 406 can generate battery disassembly instructions from a database of batteries and/or task primitives. The task planner can interface with a task primitive execution module 408. The task primitive execution module 408 can coordinate the execution of numerous and disparate disassembly tasks embedded in the task primitives, including sequential or parallel execution of the task primitives to achieve successful battery disassembly. The ROS 402 can translate and/or transmit the task primitive execution module 408 commands into a low-level control module 410.

A system monitor 430 can monitor, evaluate and/or record data related to the performance of battery disassembly tasks. In some embodiments, the system monitor 430 includes a safety monitor 432. The safety monitor can detect a variety of conditions that pose a safety concern and can generate appropriate action, whether in the form of generating an alarm and/or shutting down various parts of the ABDS. For example, the safety monitor 432 can detect an unsafe battery temperature, based on temperature sensors output, and generate a corresponding response. For example, detecting unsafe battery temperatures can trigger shutting down the disassembly operations and alerting a human technician. In some embodiments, the ABDS operates or expects to operate in an environment, where humans are not in the near vicinity of the ABDS. If the presence of a human in the near vicinity of the ABDS is detected, the safety monitor 432 can generate a corresponding response, such as producing various visual or auditory alarms via the HMI 404, or other components, and/or shutting off various hardware components of the ABDS.

The system monitor 430 can include a recorder 434. The recorder 434 can record the disassembly operations in various aspects. For example, the recordings can include sensor outputs related to various statuses of robotic agents, tools, and/or battery features. The recordings can be used to better tune or improve the subsequent disassembly instructions and/or the task primitives. In other words, the output of the recorder 434 can contribute to the training of the ABDS. In some embodiments, the recorder 434 can record outputs of all or some low-level control module 410, including the output of tool sensors 420, and sensor control module 422, when a human technician is operating a tool. The recorded data in this manner can be used to generate or tune the task primitives.

The system monitor 430 can include an evaluation module 436, which can query or receive the statuses of the performance of various task primitives and their success or failure. Additionally, the evaluation module 436 can query or receive state or pose data related to the robotic agents, and/or the battery features to assist in determining the success or failure of the performance of a task primitive. The evaluation module 436 receives data from various sensors, including one or more vision sensors. Depending on the output of the evaluation module 436, the task primitive execution module 408 can command a corresponding response, including for example, commanding to reperforming a task primitive, or alerting a human technician.

The low-level control module 410 can include a variety of control modules related to or corresponding to various hardware components, for example, the hardware components described in relation to the embodiment of FIG. 1. For example, a robotic agent 104 can include a robot agent control module 412, and a tool control module 416. The low-level control module 410 can also include a sensor control module 422, a motion platform control module 424, and other control modules depending on the implementation of the ABDS. The illustrated control modules are provided as examples. The described ABDS can be implemented in a variety of hardware and software components, where the illustrated components may be combined and/or broken into additional modules. For example, in some embodiments, the low-level control module 410 may be eliminated and each control module can directly interface with the ROS 402.

Various hardware components that can move or have internal motors can include motor encoders to receive low-level controls directed to controlling the operations of the motors. For example, the robot agent control module 412 can include the motor encoders 414. Similarly, the tool control module 416 can include motor encoders 418. The motion platform control module 424 can include motor encoders 426. Furthermore, some hardware components can include independent on-board and/or independent sensors. For example, the robotic agents 104 can include robot sensors. The onboard sensors can have their corresponding low-level control modules too. For example, the Robot agent control module 412 can have low-level control modules related to onboard robot agent sensors 415. The tool control module 416 can have low-level control modules related to onboard tool sensors 420. The motion platform control module 424 can have low-level control modules related to onboard motion platform sensors 428.

The ABDS can have various offboard sensor systems independent of moving hardware. Examples of offboard sensor systems can include vision, proximity and contact sensors. The low-level control module 422 can include sensor control module 422 directed to offboard sensor systems.

Furthermore, the low-level controls module 410 can receive and/or translate task primitives into action by one or more corresponding hardware components. The flow of information between the low-level control modules and higher-level software components, such as Task planner or the system monitor, is bidirectional. For example, various hardware components can broadcast their status, their pose, or their location through the ROS 402 to the HMI 404, the task primitive execution module 408, and/or the system monitor 430. Alternatively, or in addition the low-level control modules can be polled or queried by the higher-level software components.

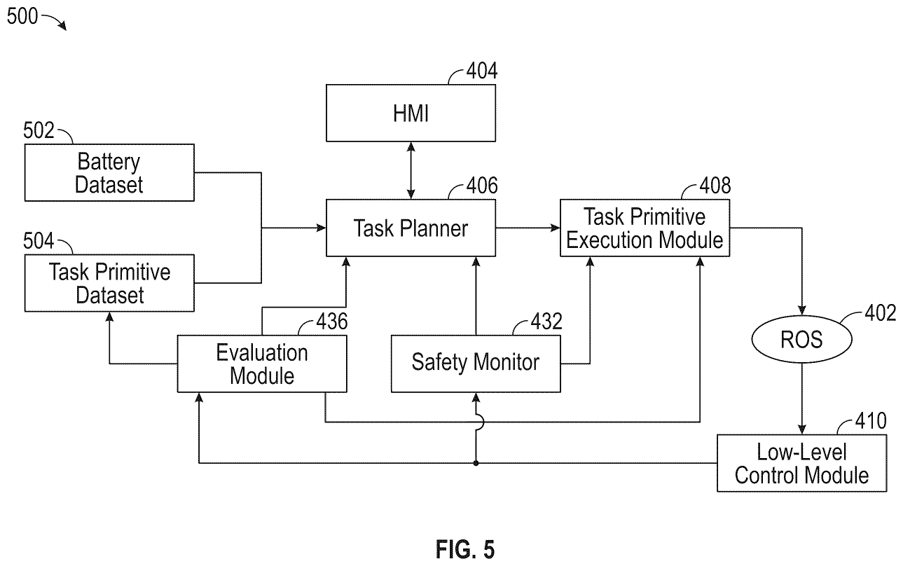

FIG. 5 illustrates a diagram 500 of an alternative implementation of the software architecture of the ABDS. The task planner 406 can interface with a battery database 502 to obtain various specification documents related to a battery. The battery dataset 502 can include computer diagrams, models, computer aided design (CAD) drawings of a battery architecture, as well as manufacturer documentation on a battery architecture, components, and disassembly. For batteries missing OEM resources, the battery dataset 502 can be developed, based on historical data, obtained from prior disassembly of identical or similar battery types. For a given battery architecture, the task planner 406 can generate battery disassembly instructions from a task primitive dataset 504.

The task primitive dataset 504 can include a library of task primitives. Each task primitive is a combination of a tool, one or more motion trajectories, and an operation of the tool on a battery feature. The task primitive dataset 504 can be generated by a variety of methods, including by monitoring and/or recording a battery disassembly performed by trained technicians, utilizing the same tools associated with the task primitives, attaching sensors to tools and/or gloves worn by technicians to record motion trajectories and quantifiable tool operation parameters, when the human technicians operate a tool on a battery feature. The recorded motion trajectories and tool operations can be used as initial seed data for generating the task primitive dataset 504. The task primitives can also be generated by simulation or modeling, for example, by use of computer aided manufacturing (CAM) techniques. Task primitives can initially be generated by any method as described herein and later be modified or improved, based on monitoring, evaluation, and observation of quantifiable parameters, received from low-level control module 410.

In some embodiments, the recorded data from a human technician, operating a tool on a battery feature, is also augmented with recorded data from other sensors, consequently, recording a state of the ABDS, the battery and the battery feature, which can contribute to the robustness of the task primitives generated from the recorded data. In other words, the recorded state and condition information in combination with the recorded motion trajectories can help inform the generation of a task primitive. In some embodiments, the recorded historical data obtained from recording a technician or from other means can be annotated with task progression milestones. The annotated milestones can be used to evaluate the progression of performance of an assembly task. For example, the evaluation module 436 can use the milestones to determine success or failure of performance of a task primitive.

The task primitive dataset, initially obtained from manual assembly of one battery, can be used in automated disassembly of another battery, whose features and disassembly tasks are similar or compatible. In other words, task primitives can be developed for one battery type and used on other battery types. Task primitives, whose motion trajectories, tools, and actions perform the same function, can be shared among multiple battery types, regardless of the differences that are immaterial to the performance of the disassembly tasks embedded in the task primitives. As an example, a task primitive directed to disconnecting an electrical connector with a quick-release tab, generated, and obtained from one battery, can be stored in the task primitive dataset 504, and used for the disassembly of another battery type. Such task primitives can be shared amongst different battery types, regardless of different connector shapes and sizes because the underlying motion trajectories, tools and tool operations are the same no matter the size and shape of the connector and/or the release tabs. In each instance, the tool operations include the same operations, such as grasping, pulling, or exerting pressure, regardless of the connector shape and size.

The motion trajectories of a task primitive can include more than one category. For example, motion trajectories associated with the movement of a robotic agent, while performing a disassembly task on a battery feature can be labeled as tool-usage trajectories in the task primitive dataset 504. Tool-usage trajectories may be fixed or may have to go through additional steps before being modified. On the other hand, motion trajectories associated with movement of a tool to a battery feature, in preparation or anticipation of performance of a battery disassembly task, can be labeled as free-space motion trajectories, which can be replaced or modified with other motion trajectories. In some embodiments, the task planner 406 and/or the task execution module 408 can modify and/or replace the free-space motion trajectories to generate a collision-free motion trajectory for movement of a robotic agent 104, while maintaining the tool-usage motion trajectories unchanged.

The software architecture of the embodiments of FIGS. 4 and 5 are provided as examples. Persons of ordinary skill in the art can combine and/or modify the described architecture diagrams, without departing from the spirit of the described technology. For example, the functionality of some components can be further divided into additional components. Alternatively, the functionality of some components can be combined, reducing the number of components. Other modifications can also be performed by a person of ordinary skill in the art, without departing from the spirit of the disclosed technology.

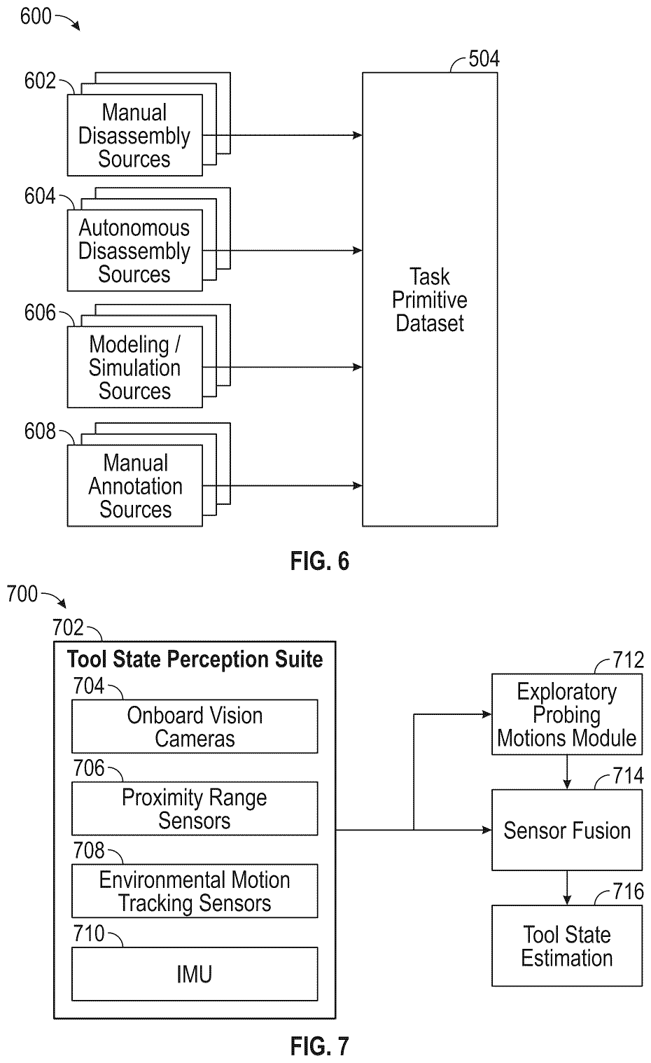

FIG. 6 illustrates a block diagram 600 of an overview of example sources and techniques for generating the task primitive dataset 504. Example sources as described herein can include manual disassembly sources 602, autonomous disassembly sources 604, modeling or simulation sources 606, and manual annotation sources 608. These sources are provided as examples. Not every source is required in every implementation, and other sources of generating the task primitives can also be added. Furthermore, the sources can be combined. Manual disassembly sources 602 can include recording motions of a human technician, one or more tools, and the ABDS sensor outputs and parameters, during one or more manual disassembly tasks performed by the human technician, using the tools. Autonomous disassembly sources 604 can include recorded ABDS data, for example, data from high-level and/or low-level components, collected during performances of prior autonomous disassembly tasks. Modeling or simulation sources 606 can include generating task primitive data from one or more software models and/or simulation, for example, using modeling or simulation techniques similar to the techniques used when generating cutting toolpaths in computerized numerical control (CNC) manufacturing applications. Manual annotation sources 608 includes annotating a task primitive or a series of task primitives with milestones for success and failure, and/or other data.

The task primitive dataset 504 can be continuously updated, or tuned using the resources 602-608, or other resources. Some parameters used for tuning can include, task primitive execution time, success/failure rate, degree of tool wear, quantified risk of damage to the battery when performing a task primitive, or a series of tasks primitives, and other parameters.

FIG. 7 illustrates a block diagram 700 of some example components, used in generating an estimation of a tool state, which, in turn, can be used to generate the manual disassembly sources 602 and/or autonomous disassembly sources 604. A tool perception suite 702 can provide a plurality of sensor readings to a sensor fusion module 714. For example, the tool perception suite 702 can include onboard vision cameras 704, coupled with or mounted on the tool, proximity, or range sensors 706, environmental motion tracking sensors 708, and inertial measurement units 710. Some sensors and components of the tool state perception suite 702 are onboard sensors coupled with or mounted on the tool, and some sensors are offboard or environmental, mounted on locations outside the tool. The combination of the onboard and offboard sensor outputs can be used to generate and/or track a state of a tool during manual or autonomous performance of a task primitive. Exploratory probing motions module 712 can provide additional sensor output to assist in estimating and/or tracking a tool state throughout the performance of a task primitive. While the accuracy of motion trajectories can initially rely on no-contact vision systems, the accuracy can be improved through further exploratory motions using inputs from additional sensors, such as rangefinder sensors (e.g., infrared rangefinders), or proximity switches. In some embodiments, when some sensors are mounted to motion platforms 106, they can be better positioned in their optimal operating ranges. In the case of contact/proximity switches, the motion platforms 106 can perform move-to-contact procedures and leverage a physical contact as a positional reference.

The sensor fusion module 714 can combine the sensor readings from the tool perception suite and the exploratory probing motions 712 to generate the tool state estimation 716. In some embodiments, the tool and/or the tool environment can include physical or virtual reality markers to provide reference or orientation points for interpreting sensor data, and for generating the tool state estimation 716. The sensor fusion module 714 can use virtual reality and filmmaking motion capture techniques.

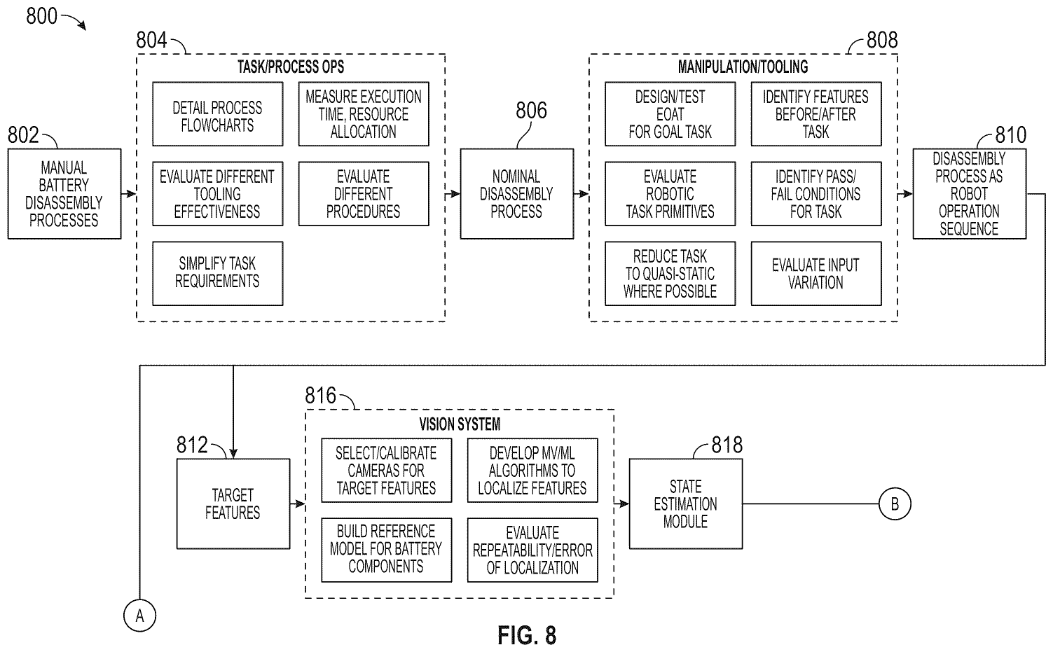

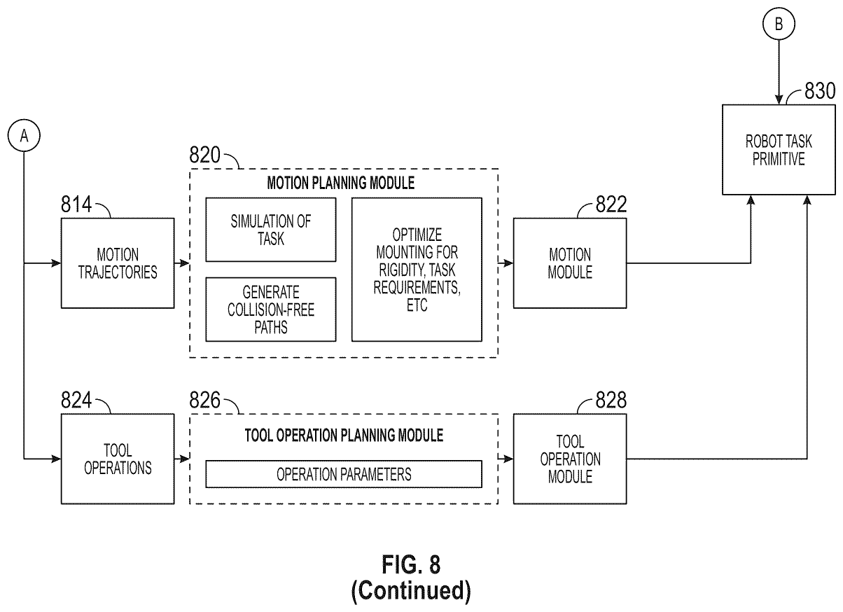

FIG. 8 illustrates a block diagram 800 of example process steps to generate robotic task primitives, from manual battery disassembly processes. In some embodiments, manual battery disassembly processes 802 can be used to generate task/process operations 804. Task/process operations 804 can include synthesizing, gathering, or generating information such as detailed process flowcharts, execution time measurements, allocation or assignment of resources, evaluation of effectiveness of various tooling relative to a task, and information or processes for task simplification. Task/process operations 804 can be used to generate preliminary or nominal disassembly processes 806.

The manipulation/tooling stage 808 can receive the nominal disassembly processes 806, as a starting point, and design and/or test an end of arm tool (EOAT) for a disassembly goal or task. The manipulation/tooling stage 808 operations can further include identifying target features and/or state of target features both before and after successful completion of a task, identifying evaluation parameters of a robotic task primitive, identifying passing, and failing conditions for a task, where possible reducing tasks to quasi-static tasks, and evaluating input variation. Performing the operations of the manipulation/tooling stage 808 can yield a disassembly process as a robotic operation sequence 810.

The robotic operation sequence 810 can yield target features 812, the motion trajectories 814 and tool operations 824. The target features 812 can include battery features that are subjects of disassembly tasks, their location, and their state before and after performance of a disassembly task. The motion trajectories 814 can also include poses or states of tools and/or robotic agents coupled with the tools. The target features 812 can be the subject of operations of a vision system 816. The operations of the vision system 816 can include selection and/or calibration of cameras for the target features, developing, and/or configuring machine vision and/or machine learning modules directed to detecting and localizing the target features. Localizing in this context refers to estimating or determining the location of a target feature, relative to a reference. Additional operations of the vision system 816 includes building reference visual models for various battery types and the battery components in each battery type and developing parameters or framework for evaluating repeatability of a target feature localization algorithm, as well as any expected error margin for a localization algorithm. The operations of the vision system 816 can be used to build a state estimation module 818. The state estimation module 818 can identify target features and determine or estimate their locations within a known margin of error.

The motion trajectories 814 can be the subject of operations of a motion planning module 820. Some example operations of the motion planning module 820 can include, simulating the performance of a disassembly task, generating collision-free paths to move a robotic agent to a target feature, and various optimization, such as mounting optimization for rigidity and/or improved task performance. The output of the motion planning module 820 can be used to build a motion module 822. The motion module 822 can include the motion trajectories of a disassembly task, including for example, the motions to move a robotic agent armed with a tool to a target feature on a battery, and the motion trajectories of the tool during operation or performance of the disassembly task on the target feature.

The tool operations 824 can include data, such as type and selection of the tools, sub-tools, accessories, and tool operation requirements for performance of a disassembly task. The tool operations 824 can be the subject of a tool operations planning module 826. The tool operation planning module 826 generates tool operation parameters, depending on the type of tool and the requirements of the disassembly task. Tool operation parameters can be constrained by both the requirements of the disassembly task and by safety parameters. In other words, tool operation parameters can include parameters to perform a disassembly task and parameters to monitor for safety purposes, such as avoiding thermal runaway and unsafe currents and voltages at various surfaces of the battery. The output of the tool operation planning module 826 can be used to build a tool operations module 828. The tool operations module 828 can provide the tool selection, and the tool operating parameters for a task primitive. The state estimation module 818, the motion module 822 and the tool operations module 828 can be used to build the robotic task primitives 830.

The task planner 406 and/or the task primitive execution module 408 can be configured to account in variation in their inputs and modify either the task primitives or a sequence of task primitives to accomplish a disassembly task. Variation in input refers to real-world changes that can exist between the parameters of a battery, or battery feature, relative to the parameters and conditions that are stored for a task primitive, or a series of task primitives. If deviation between observed parameters and stored parameters for a task primitive are minimal, the task primitive can be executed, without modification. If the observed parameters differ, the task primitive, or a series of task primitives can be modified. An example of the modification can include rerunning a task primitive (e.g., a task primitive directed to “cutting”), until the objective of the task primitive is achieved.

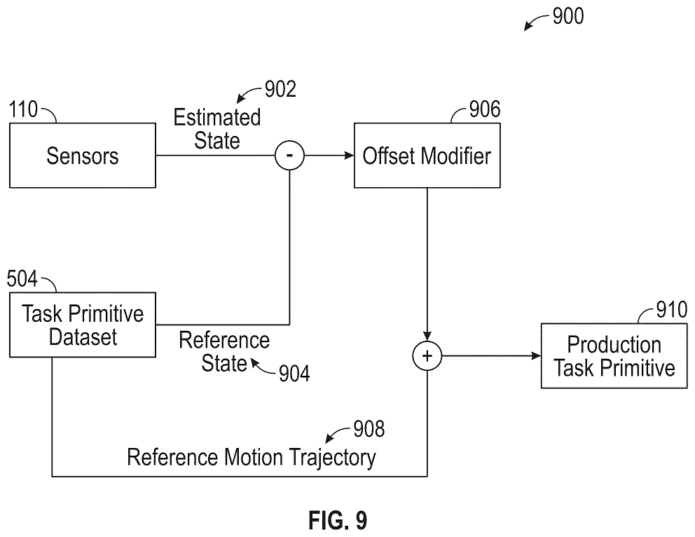

FIG. 9 is a block diagram 900 of an example of the operations of the task planner, when modifying a reference task primitive. The task primitive dataset 504 can provide the reference task primitives. Each task primitive can include expected conditions and parameters of the task, tooling, and motion trajectories of the task primitive. In other words, a task primitive includes the “reference state,” under which the task primitive is expected to perform. As described earlier, the reference state and the associated parameters can be generated or obtained when building the task primitive dataset 504. Subsequent batteries, of even the same type, can have variations in parameters and conditions that can affect the performance of the task primitive. These variations can be on a spectrum, minimal or substantial. For example, not every battery feature, subject of a task primitive, is affixed to the battery structure, without movement. Some fasteners, holding harnessing, for example, can have a range of free motion.

In some cases, the location of an expected feature for a task primitive can be part of the variation between a task primitive, stored in the task primitive dataset 504, and a battery being disassembled. In this scenario, the sensors 110 can be queried to build an estimated state 902. The task primitive dataset 504 can be polled to retrieve a reference state 904. The difference between the estimated state 902 and the reference state 904 can yield an offset modifier 906. The task primitive dataset 504 and/or the reference state 904 can be used to retrieve a reference motion trajectory 908. Combining the reference motion trajectory 908 with the offset modifier 906 can yield a production task primitive 910. The same framework illustrated in the diagram 900 can be applied to determining other modifications to the task primitives, based on detecting the output of the sensors 110 and comparing the observed sensor outputs to the reference task primitives.

### Hardware Architecture

Several possible combinations of motion systems and tooling to position/maneuver tooling around an EV battery can be used. Example hardware architectures can include static manipulator arms, static manipulator arms and mobile battery station, overhead gantry system, mobile manipulator arms on motion extenders, complex tooling/gantry on single large robotic arms, and others. In some embodiments, robot manipulators, mounted statically around a battery pack workspace can be used. In another embodiment, robot manipulators, mounted on a rail and/or a gantry for increased workspace can be used. In some embodiments, a gantry system for increased rigidity and payload can be used. In some embodiments, winch systems, for lifting heavy payloads, can be used. The winch systems can include attachment points guided and affixed with assistance from a secondary robotic arm. In some embodiments, a combination of industrial robot arms can be used for larger payloads and heavy-duty, high-force tasks, while cobots can be used for less demanding tasks.

Tooling can be operated at some selected pose relative to a target feature on the battery. This does not necessarily require that tooling is moved to a target feature with an anthropomorphic, serial-chain manipulator, nor does it require the tooling to be moved at all. In some embodiments, the target battery feature can be moved to the tooling. Motion systems, such as serial-chain manipulators can be generalized positioning systems that can be characterized by reach, payload, rigidity, and resolution. Reach and payload can be correlated, but rigidity and resolution can vary across the system workspace. Selection of the motion system can determine whether tooling can be adequately deployed for a target task. Selection of the motion system can in turn be informed by requirements of assembly tasks embedded in the task primitives. High-payload tasks, such as extracting heavy battery modules and detaching subcomponents that may be partially affixed to the main battery structure with adhesives, can be performed with corresponding heavy-duty motion systems. Task primitives, embedding dexterous, precision disassembly tasks, such as decoupling small connectors, or removing fasteners, can be performed by more light-duty motion systems.

An example disassembly workspace can include several robotic arm manipulators, statically affixed around a battery. The manipulators may be affixed to the ground, or to an overhead mounting point, relative to the battery. They can include fixed tooling, or they can utilize a tool changer to swap tooling from a cache of tools. A fixed manipulator may not necessarily be able to fully access all sections of a battery. This scenario can be addressed by the addition of more manipulators or conveyance mechanisms beneath the battery or manipulator arms. The addition of motion extenders, which can be on a mobile base, or on additional motion axes, supporting one or more manipulator arms, having multiple degrees of freedom (DOF) can decouple the payload and reach relationships, where used. Alternatively, an inverse conffiiguration, where advanced tooling integrating precision motion axes for dexterous tasks are mounted to a large manipulator, can increase the likelihood that a base arm manipulator can support high payload tasks and gross motions, while the tooling with redundant motion axes can separately handle the fine-positioning motions and task involving fine positioning.

### Some Advantages of the Embodiments

Robotics and automation excel in the timing, speed, precision, and repeatability of executing disassembly tasks. Furthermore, automating a battery disassembly task through robotics can allow for more efficient solutions in battery disassembly when compared to the manual procedures. Destructive dismantling may be more viable, as heavier tooling can be utilized, and there could be less concern regarding potential damage, as the cutting paths can be more tightly controlled position-wise. Without a human technician in-the-loop, the discharge step in battery disassembly can be delayed or skipped altogether, as ensuring high voltage safety is less of a concern. This can allow for more efficient determination of SOH, because the discharge process, when using autonomous disassembly can occur at other times during the disassembly, compared to having to be performed relatively early in the process, when human technicians are performing manual disassembly. This can substantially increase the efficiency of battery SOH analysis in parallel with increasing the efficiency and safety of the disassembly.

Furthermore, scaling up the machinery size can also allow for performing operations that otherwise would require the coordination of multiple technicians, for example when lifting large covers or heavy modules. Similarly, high parallelizable tasks, such as fastener removal, can leverage a robotic system's relatively faster speeds or a non-anthropomorphic configuration of multiple manipulator arms to expedite performing of the task.

In some cases, the ABDS can utilize tools that are more suited to performing a disassembly task that a human technician may not be able to use during manual disassembly operation, due to safety concerns, or when the tool may be too heavy or difficult for a human technician to operate throughout a typical disassembly workday. For example, larger cutting tools can be difficult for human technicians to use on a routine basis, while they can be more suited for avoiding stripped fasteners or for performing intensive destructive disassembly. Other tools, such as waterjets, high-powered lasers, endmills and angle grinders may be more suitable tools for accomplishing a disassembly task, but unsafe or inefficient for manual disassembly.

Another advantage of autonomous battery disassembly is the live or continuous safety monitoring, as described in relation to the feature of the safety monitor 432. Such monitoring can better detect unsafe conditions and more efficiently respond to unsafe conditions. For example, the ABDS can detect unsafe thermal runaway temperatures in time for implementing remedial measures. Autonomous battery disassembly systems can also be implemented to provide a safe physical distance between the system components and any human technician working in the same environment. For example, human technicians monitoring the ABDS can rely on the HMI 404 to increase their physical distance from the battery.

Other advantages of autonomous battery disassembly include reduction of assembly mistakes that can occur, when multitude of battery types can each have different disassembly procedures, without availability of documentation to provide disassembly guidance. Furthermore, the ABDS, operated over time, can generate a knowledge database of more precise disassembly instructions for a more comprehensive collection of battery types, as well as using the knowledge database, and the recordation and evaluation of prior disassembly jobs to further improve and tune the disassembly instructions in the knowledge database.

Other advantages of autonomous battery disassembly can be envisioned by persons of ordinary skill in the art, given the benefit of the described embodiments.

### Example Implementation Mechanism-Hardware Overview

Some embodiments are implemented by a computer system or a network of computer systems. A computer system may include a processor, a memory, and a non-transitory computer-readable medium. The memory and non-transitory medium may store instructions for performing methods, steps and techniques described herein.

According to one embodiment, the techniques described herein are implemented by one or more special-purpose computing devices. The special-purpose computing devices may be hard-wired to perform the techniques, or may include digital electronic devices such as one or more application-specific integrated circuits (ASICs) or field programmable gate arrays (FPGAs) that are persistently programmed to perform the techniques, or may include one or more general purpose hardware processors programmed to perform the techniques pursuant to program instructions in firmware, memory, other storage, or a combination. Such special-purpose computing devices may also combine custom hard-wired logic, ASICs, or FPGAs with custom programming to accomplish the techniques. The special-purpose computing devices may be server computers, cloud computing computers, desktop computer systems, portable computer systems, handheld devices, networking devices or any other device that incorporates hard-wired and/or program logic to implement the techniques.

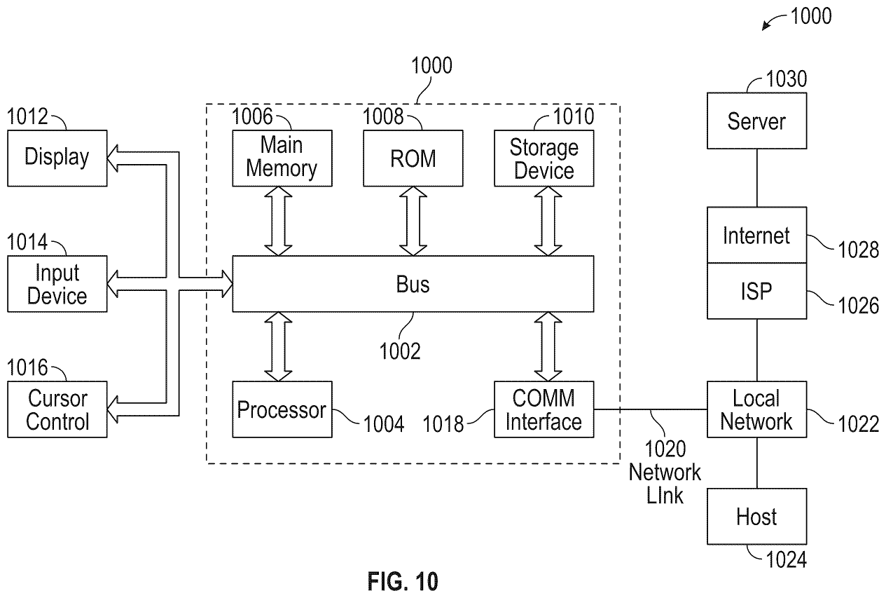

For example, FIG. 10 is a block diagram that illustrates a computer system 1000 upon which an embodiment of can be implemented. Computer system 1000 includes a bus 1002 or other communication mechanism for communicating information, and a hardware processor 1004 coupled with bus 1002 for processing information. Hardware processor 1004 may be, for example, special-purpose microprocessor optimized for handling audio and video streams generated, transmitted or received in video conferencing architectures.

Computer system 1000 also includes a main memory 1006, such as a random access memory (RAM) or other dynamic storage device, coupled to bus 1002 for storing information and instructions to be executed by processor 1004. Main memory 1006 also may be used for storing temporary variables or other intermediate information during execution of instructions to be executed by processor 1004. Such instructions, when stored in non-transitory storage media accessible to processor 1004, render computer system 1000 into a special-purpose machine that is customized to perform the operations specified in the instructions.

Computer system 1000 further includes a read only memory (ROM) 1008 or other static storage device coupled to bus 1002 for storing static information and instructions for processor 1004. A storage device 1010, such as a magnetic disk, optical disk, or solid state disk is provided and coupled to bus 1002 for storing information and instructions.

Computer system 1000 may be coupled via bus 1002 to a display 1012, such as a cathode ray tube (CRT), liquid crystal display (LCD), organic light-emitting diode (OLED), or a touchscreen for displaying information to a computer user. An input device 1014, including alphanumeric and other keys (e.g., in a touch screen display) is coupled to bus 1002 for communicating information and command selections to processor 1004. Another type of user input device is cursor control 1016, such as a mouse, a trackball, or cursor direction keys for communicating direction information and command selections to processor 1004 and for controlling cursor movement on display 1012. This input device typically has two degrees of freedom in two axes, a first axis (e.g., x) and a second axis (e.g., y), that allows the device to specify positions in a plane. In some embodiments, the user input device 1014 and/or the cursor control 1016 can be implemented in the display 1012 for example, via a touch-screen interface that serves as both output display and input device.

Computer system 1000 may implement the techniques described herein using customized hard-wired logic, one or more ASICs or FPGAs, firmware and/or program logic which in combination with the computer system causes or programs computer system 1000 to be a special-purpose machine. According to one embodiment, the techniques herein are performed by computer system 1000 in response to processor 1004 executing one or more sequences of one or more instructions contained in main memory 1006. Such instructions may be read into main memory 1006 from another storage medium, such as storage device 1010. Execution of the sequences of instructions contained in main memory 1006 causes processor 1004 to perform the process steps described herein. In alternative embodiments, hard-wired circuitry may be used in place of or in combination with software instructions.

The term “storage media” as used herein refers to any non-transitory media that store data and/or instructions that cause a machine to operation in a specific fashion. Such storage media may comprise non-volatile media and/or volatile media. Non-volatile media includes, for example, optical, magnetic, and/or solid-state disks, such as storage device 1010. Volatile media includes dynamic memory, such as main memory 1006. Common forms of storage media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM, NVRAM, any other memory chip or cartridge.

Storage media is distinct from but may be used in conjunction with transmission media. Transmission media participates in transferring information between storage media. For example, transmission media includes coaxial cables, copper wire and fiber optics, including the wires that comprise bus 1002. Transmission media can also take the form of acoustic or light waves, such as those generated during radio-wave and infra-red data communications.

Various forms of media may be involved in carrying one or more sequences of one or more instructions to processor 1004 for execution. For example, the instructions may initially be carried on a magnetic disk or solid state drive of a remote computer. The remote computer can load the instructions into its dynamic memory and send the instructions over a telephone line using a modem. A modem local to computer system 1000 can receive the data on the telephone line and use an infra-red transmitter to convert the data to an infra-red signal. An infra-red detector can receive the data carried in the infra-red signal and appropriate circuitry can place the data on bus 1002. Bus 1002 carries the data to main memory 1006, from which processor 1004 retrieves and executes the instructions. The instructions received by main memory 1006 may optionally be stored on storage device 1010 either before or after execution by processor 1004.

Computer system 1000 also includes a communication interface 1018 coupled to bus 1002. Communication interface 1018 provides a two-way data communication coupling to a network link 1020 that is connected to a local network 1022. For example, communication interface 1018 may be an integrated services digital network (ISDN) card, cable modem, satellite modem, or a modem to provide a data communication connection to a corresponding type of telephone line. As another example, communication interface 1018 may be a local area network (LAN) card to provide a data communication connection to a compatible LAN. Wireless links may also be implemented. In any such implementation, communication interface 1018 sends and receives electrical, electromagnetic or optical signals that carry digital data streams representing various types of information.

Network link 1020 typically provides data communication through one or more networks to other data devices. For example, network link 1020 may provide a connection through local network 1022 to a host computer 1024 or to data equipment operated by an Internet Service Provider (ISP) 1026. ISP 1026 in turn provides data communication services through the world wide packet data communication network now commonly referred to as the “Internet” 1028. Local network 1022 and Internet 1028 both use electrical, electromagnetic or optical signals that carry digital data streams. The signals through the various networks and the signals on network link 1020 and through communication interface 1018, which carry the digital data to and from computer system 1000, are example forms of transmission media.

Computer system 1000 can send messages and receive data, including program code, through the network(s), network link 1020 and communication interface 1018. In the Internet example, a server 1030 might transmit a requested code for an application program through Internet 1028, ISP 1026, local network 1022 and communication interface 1018.

The received code may be executed by processor 1004 as it is received, and/or stored in storage device 1010, or other non-volatile storage for later execution.

### Non-Intrusive Battery Assessment System (NBAS)

Portions of the autonomous battery disassembly system, described above, can be used in combination with one or more non-intrusive battery assessment systems. The decision to perform disassembly of a secondary battery can relate to whether the state of health of the battery, makes the battery suitable for reusing, repurposing, or recycling, based on technical or economical consequences of the state of health of the battery. While state of health (SOH) may not uniformly be defined in the battery industry, some state of health measurements are expressed in terms of percentage derived from one or more electrical characteristics of a battery, such as internal resistance, impedance, conductance, capacity, voltage, self-discharge, ability to accept a charge, number of prior charge-discharge cycles, age of the battery, temperature of the battery during operation, energy charged and discharged, and/or other parameters.

The aging and degradation mechanisms of secondary batteries can be a non-linear, chemical and/or mechanical occurrence, such that applying a uniform reusing, repurposing, or recycling strategy to all batteries, can be non-optimal. Batteries can also include modules of cells, which in some instances can age or degrade at various rates. While battery management systems can, to some extent, provide uniform aging amongst battery cells, in real-world applications, battery packs can experience both uniform and non-uniform aging. Some battery packs can experience defects or degradation only in a handful of cells, amongst hundreds or thousands of cells. In these scenarios, an optimum or near optimum, reusing, repurposing or recycling strategy may be to extract the defective cells, and repair or replace them to safely give the battery a new life in the same application. For other batteries, degradation due to aging can affect the cells, or a collection of the cells, to some extent, yet the pack as a whole, or a substantial portion of the pack can be suitable for repurposing in another application or another industry. For example, some used EV or HEV batteries may be suitable as electrical grid storage or backup batteries. In other instances, the damage or degradation to the battery cells can be severe enough that there is no economic value in performing disassembly. Such batteries are typically good candidates for sending to a recycling plant, which can recycle them to raw material.

Another parameter that can substantially affect the decision to reuse, repurpose or recycle a battery is the remaining useful life (RUL) of the battery. RUL can also be non-linear and difficult to determine, even when the present SOH of the battery, and the associated parameters, are known or can be measured. For example, in some instances, a cell or a collection of the cells are near their failure point, but still provide specification-matching parameters that indicate a healthy state. Consequently, accurately predicting RUL of the battery can have a positive impact on the battery industry.

Another challenge in determining a suitable reuse, repurpose or recycle strategy for a battery is the ability to efficiently and accurately determine the SOH and RUL of a substantial number of batteries, and/or cells, in a reasonable amount of time. Typical used battery depots may receive hundreds of batteries a day. In the case of EVs and HEVs, each battery pack can include hundreds of modules, or thousands of cells. Current methods of measuring SOH parameters typically involve performing charging and discharging cycles on the battery, the cells or a collection of the cells. Charging and discharging can take hours, and in some instances use expensive charge/discharge stations. Since a battery pack usually provides a single set of positive and negative terminals for the whole pack, measuring SOH, using those terminals can provide SOH parameters for the pack as a whole, which can be inadequate or suboptimal for making a reuse, repurpose, or recycling decision for the battery. Traditional charge and discharge measurement of SOH can be utilized at the cell-level, but some amount of disassembly may be necessary to gain access to cell terminals, making the second life determination, more inefficient. While some amount of module-level or cell-level SOH measurement can be performed through an onboard battery management system (BMS), many such systems use proprietary and closed-off controls, making the SOH measurement more difficult or impractical.

Another challenge facing the battery industry is a lack of a uniform and standard system of measuring and publishing the SOH of a battery. Due to the non-linear and non-deterministic nature of chemical degradation, relative to measurable electrical parameters of a battery, outlining a uniform standard of SOH and RUL has been difficult. Therefore, the battery industry can benefit from models that can provide repeatable and consistent measurements of SOH and RUL of batteries.

These and other challenges of accurately and efficiently determining SOH and RUL of a battery or battery cells can slow down the development of the battery industry and the adoption of the technologies that rely on batteries. The described embodiments can address several of these challenges by providing autonomous, non-intrusive battery measurement systems.

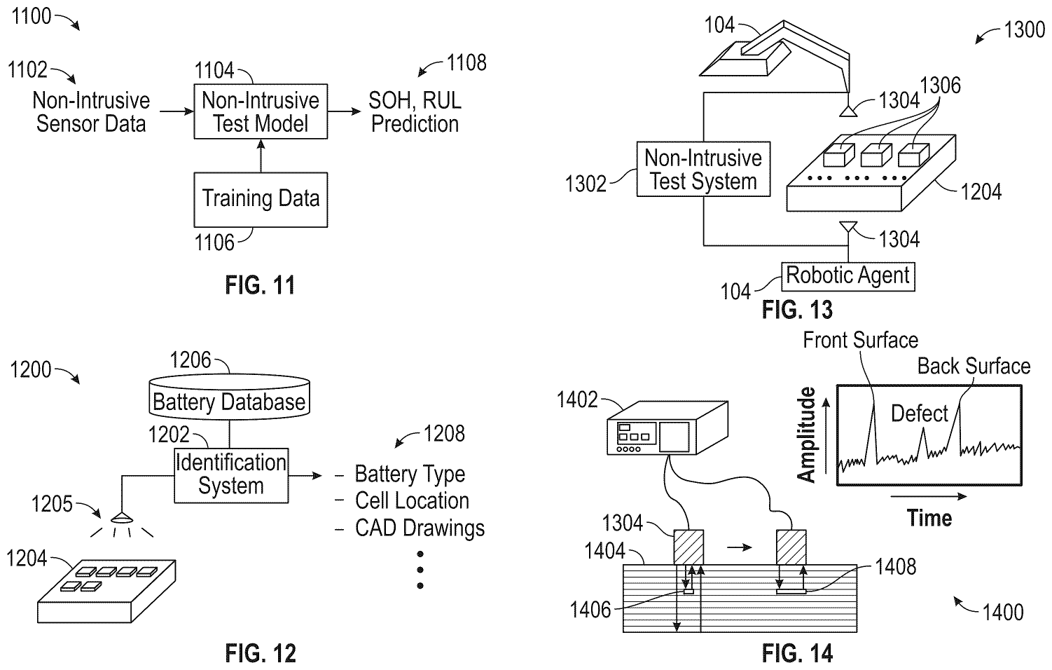

FIG. 11 illustrates a diagram 1100 of an embodiment utilizing non-intrusive testing to determine SOH and RUL of a battery. Non-intrusive sensor data 1102 are received by a non-intrusive test model (NTM) 1114. The NTM 1104 can be trained with training data 1106, and output a predication or determination of the SOH and RUL of a battery 1108. Non-intrusive sensor data 1102 can be obtained from various sources, depending on the implementation of the embodiments. In one embodiment, ultrasonic sensors can be coupled with one or more robotic agents 104. In another embodiments, robotic agents 104 can be armed with other non-intrusive scanning and measurement sensors, such as those used in computed tomography (CT) scanning, X-ray scanning, or other non-intrusive testing systems. These systems and sensors can conduct measurements by making contact with, or being in near proximity of, the perimeter of a battery pack, or the cells in the battery pack. The ABDS embodiments, which can be configured to move a tool to a particular location on a battery can be used to move one or more non-intrusive test sensors to various locations on the battery, where the sensors can conduct non-intrusive tests and collect test data. In some embodiments, the non-intrusive sensor data 1102 can be received from one sensor, for example an ultrasound transducer. In other embodiments, more than one sensor, for example two ultrasonic sensors (a transmitter and a receiver) can be used. In other embodiments, two sensors and a reflector, for example, a transducer and a reflector can be used. In other embodiment, the non-intrusive sensor data 1102 can be generated by an array of sensors, and coupled to more than one or more robotic agents 104. Other numbers and configurations of the non-intrusive test sensors are also possible, depending on the non-intrusive testing system used to implement the embodiments.

The non-intrusive test model 1104 can be implemented with or without using artificial intelligence techniques. For example, the non-intrusive test model 1104 can determine anomalies in the non-intrusive sensor data 1102, based on rules and thresholds. When using ultrasound sensors, an amplitude graph of the reflection of the sound waves transmitted through the battery or battery cells, plotted versus time, can yield structural information about the battery that can be correlated with SOH or RUL of the battery. In the case of large defects, the backside reflection may be missing in the amplitude versus time plot. Other algorithms and techniques can also be used for detecting battery or cell defects and/or correlating the sensor data 1102 to the SOH and RUL.

The NTM 1104 can also be implemented using artificial intelligence (AI) models. Training data 1106 can provide a baseline for training the NTM 1104. In this scenario, electrical testing, such as performing charging and discharging cycles can provide a baseline training data. Various degradation stages can also be simulated in test batteries, to provide training data 1106. In this scenario, a test battery can be placed under circumstances to simulate a known degradation, then scanned using the non-intrusive test sensors, and used to update the parameters of the NTM 1104. Both supervised and unsupervised AI techniques can be used. For example, supervised AI training techniques can be used to train the NTM 1104 to detect the signature indicators of various degradation mechanisms, while unsupervised AI techniques can be used to detect patterns that are indicative of various degradation mechanisms. In some embodiments, the NTM 1104 can detect sampling parameters, for testing only a selection of the cells of a battery to arrive at the SOH and RUL analysis more efficiently. In some embodiments, the NTM can provide a correlation between test data obtained from non-intrusive testing methods and various parameters related to SOH and RUL, obtained from other battery health assessment techniques.

FIG. 12 illustrates a diagram 1200 of a battery identification system, which can be used in non-intrusive testing. The battery identification system 1202 can use the vision sensors 1205 to scan the battery 1204 for various identification information, including barcodes, quick response (QR) codes, labels, unique structural or geometrical features, or any other identifying information, which can be sensed by vision sensors 105. The identification system 1202 can be in communication with a battery database 1206 to match the vision sensor output to the battery information contained in the database. When a match is detected, battery structural data 1208, such as the battery type, cell locations, computer aided drawings (CAD), and other structural data, can be extracted. The structural data 1208 can be used to plan motion trajectories to move robotic agents 104, coupled with non-intrusive test sensors, to various locations on the battery.

FIG. 13 illustrates a diagram of a non-intrusive battery assessment system (NBAS) 1300. The NBAS 1300 can utilize the embodiments of the ABDS, as described above, for example, the robotic agents 104, and the ability to plan and execute collision-free motion trajectories for precise or near precise placement of test sensors. A non-intrusive test system 1302 can be used. The non-intrusive test system 1302 can be implemented in one or more computer systems, including for example, in the computer systems 112. The non-intrusive test system 1302 can be in communication with one or more non-intrusive sensors 1304. The robotic agents 104 can accept inputs to execute motion trajectories to position the non-intrusive sensors 1304 in contact with, or in close proximity to, one or more battery cells 1306.

The type and number of the non-intrusive sensors 1304 can depend on the implementation of the NBAS 1300. For example, NBAS can be implemented using an ultrasonic system. In this scenario, the non-intrusive sensor 1304 can be an ultrasonic probe capable of transmitting sound waves through the battery 1204. As an example, the non-intrusive test system 1302 can utilize a pulse-echo method, where the non-intrusive test sensor 1304 is a transducer/receiver assembly, positioned on one side of the battery 1204, or the cells 1306. In this scenario, the transducer emits sound waves through the battery 1204, or through the cells 1306, and the receiver detects the reflections of those sound waves through the battery 1204, or the cells 1306. In some embodiments, two non-intrusive sensors 1304 utilize a through-transmission method of ultrasound by sandwiching the battery 1204, or the cells 1306. In some embodiments, the non-intrusive sensors are an array of ultrasound probes. In some embodiments, the non-intrusive sensor 1304 can be a transmitter, or emitter of a signal, and another or the same non-intrusive sensor 1304 can be a receiver, or a detector of the reflection of the signal through the material. Various arrangements of the non-intrusive sensors 1304, including sandwiching the battery, or the cells, and/or rotating in an orbit around a position on the battery, are also possible, depending on the implementation of the NBAS 1300. For example, if CT non-intrusive test system 1302 is used, the non-intrusive sensors 1304 can be in orientations other than perpendicular, relative to the plane of the battery 1204. In some implementations, the ABDS can perform some disassembly of a battery to allow for better positioning of the non-intrusive sensors 1304, relative to the cells 1306. Still in other implementations, no disassembly may be performed.

FIG. 14 is a diagram 1400 of an example implementation of the NBAS 1300, using pulse, echo signal with ultrasonic sensors. An oscilloscope 1402 can record various sensor data from the non-intrusive sensor 1304. In this example, one non-intrusive sensor 1304 is used. The sensor is moved along the top surface 1404 of the battery 1204, or the cell 1306. The non-intrusive sensor 1304 in this example can be implemented with a transducer, which can transmit sound waves through the battery and/or the cells and receive their reflection. The oscilloscope 1402 can receive the sensor readings and plot an amplitude of the received reflection wave versus time. An oscilloscope is provided as an example. In various implementations of the NBAS 1300, the sensor readings, from the non-intrusive sensor 1304, can be transmitted to a computer system 112 for processing, and/or display, instead of, or in lieu of using the oscilloscope 1402. Small defects, such as the defect 1406 may not have a substantial impact on the plot. In the case of a large defect 1408, no backside reflection may be detected in the amplitude versus time plot, indicating the existence of a defect.

Pulse-echo signal is one example of an implementation of the NBAS 1300. Other non-intrusive test systems, including some that use other ultrasonic techniques and some that do not use ultrasonic techniques can also be used to implement the NBAS 1300. Ultrasonic through-transmission, CT, and X-ray are other potential examples of implementing an NBAS 1300.

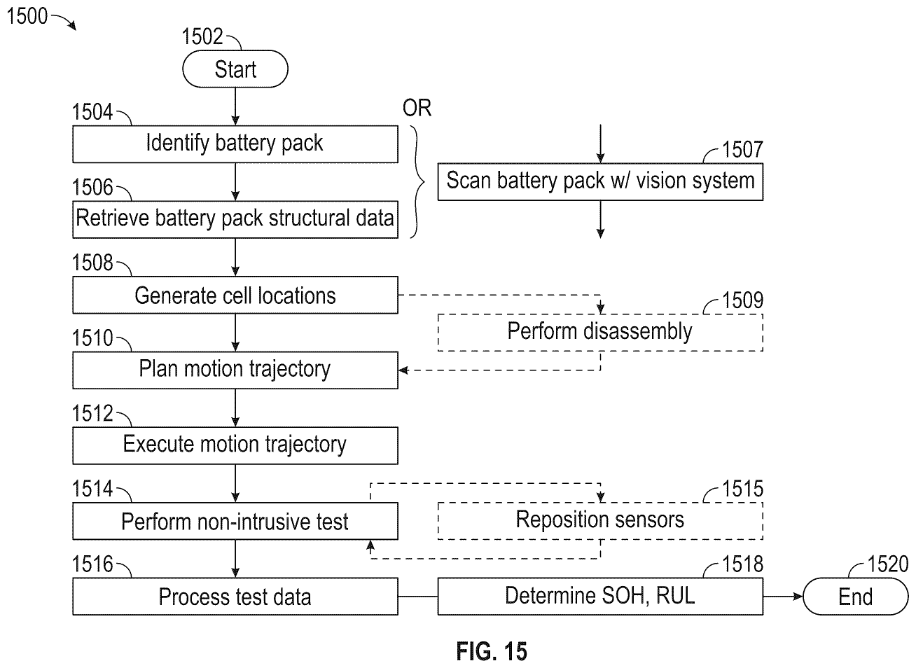

FIG. 15 is a flowchart of an example method 1500 of the operations of a non-intrusive battery assessment system (NBAS), for assessing SOH and/or RUL of a battery, according to an embodiment. Referring to FIG. 15 and previous figures, the method starts at step 1502. At step 1504, a battery identification system, such as the identification system 1202, can detect a type and/or model number of the battery, by locating and scanning a serial number, a barcode, a QR code, a label, or other visually identifying feature. At step 1506, various structural data 1208 for the identified battery is retrieved, for example, from a battery database 1206. In some embodiments, steps 1504, and 1506 can be replaced with direct scanning of the battery with a vision system to determine the locations, where non-intrusive sensors can be positioned. In this scenario, steps 1504, 1506 can be replaced with step 1507. At step 1508, cell locations of the battery can be generated. Cell locations can be extracted from the battery structural data, for example CAD drawings, specification sheets, or from the output of the vision system if step 1507 is utilized.

In some cases, step 1509, or partial disassembly may be performed to gain access to a cell, or to better position non-intrusive sensors 1304. The partial disassembly can be performed utilizing any of the embodiments of the ABDS, as described above. In other cases, step 1509 can be skipped if the non-intrusive test can be performed, without partial disassembly of the battery. At step 1510, one or more collision-free motion trajectories can be planned to move a robotic agent 104, coupled with a non-intrusive sensor 1304, to a target location, or target cell on the battery. At step 1512, the motion trajectories are executed. Performing step 1512 positions one or more non-intrusive sensors 1304 on target battery or cell locations to prepare for the performance of a non-intrusive test. Positioning of the sensors with planned motion trajectories and with the robotic agents 104 increases the reliability, consistency and repeatability of the NBAS operations, compared to manual systems. For example, non-intrusive testing can include taking multiple scans or readings, with some variations in the position of the non-intrusive sensors. Moving the sensors with robotic agents allow for more precise placement of the sensors, and using accurate historical position data for repositioning of the sensors. Step 1512 can include positioning the non-intrusive sensors 1304 to make contact with the surface 1404 of the battery or the cell. To achieve physical contact, active force through an actuator of the robotic agent 104 can be applied. Passive force, for example through spring elements, can also be used to apply a preload pressure on the non-intrusive sensor 1304 to maintain contact with the surface 1404. In other embodiments, no contact non-intrusive testing maybe performed. For example, when a displacement parameter, indicating a distance between the non-intrusive sensor 1304 and the surface 1404 is known, no contact non-intrusive testing can be performed.

At step 1514, the non-intrusive test system 1302 can perform testing and collect test data. In some instances, step 1515 can be performed, which includes repositioning the non-intrusive sensors 1304, if the prior test data is noisy or unreliable, or to increase the resolution of the test result. For example, in some embodiments, each scan may be performed multiple times depending on the quality of the recorded signal. Issues with sensor placement, exterior physical damage to the cell, or obstructions may limit the quality of the non-intrusive signal. It may be beneficial for the system to re-scan several times at each point and only utilize the cleanest signal from the collection of attempts.

When NBAS is implemented with ultrasonic, the placement of non-intrusive sensors 1304, relative to a target cell can have a substantial impact on the quality of the captured test data. In some embodiments, the decision to execute step 1515 and reperform step 1514 can be made in relation to thresholds that are derived from ideally-placed, or near-ideally placed sensors under controlled circumstances. Such experiments can yield the thresholds to determine whether the test data or the test results are of acceptable quality or whether the sensors need to be repositioned and the non-intrusive tests should be reperformed. In some cases, it can be challenging to determine whether the noise or anomalies in the test data relate to the misplacement of the non-intrusive sensors 1304, or to degradation or damage in the battery. Comparison of the test results, relative to the data from ideal or near-ideal sensor placement experiments can trigger repositioning of the non-intrusive sensors 1304. If the test results still show anomalies, after a selected number of repositioning and re-scanning, the outliers can be an indication of degradation in the battery, and not due to any issues with the correct performance of the non-intrusive test.

At step 1516, the test data is processed, for example, filtered and/or checked for quality against selected specification. Step 1516 can also include processing the test data with the non-intrusive test model (NTM) 1104. At step 1518, SOH and/or the RUL of the battery is determined, based on the collected test data and/or the output the NTM 1104. The method 1500, or a selection of the steps therein, can be repeated for other cells, or portions of the battery. The number of times the method 1500 is reperformed can, in part, depend on the type of non-intrusive sensors 1304. In some embodiments, the non-intrusive sensors 1304 are implemented in an array of transducers and/or receivers, which can scan a larger section of the battery, thereby reducing the number of times the method 1500 or portions of it need to be repeated. In other embodiments, the non-intrusive sensors 1304 can be smaller, whereby multiple repeated scans at different positions can iteratively build the test result. In other embodiments, the number of times the method 1500 or a portion of it is repeated, is reduced by choosing a selection of cells to scan. Cell sampling can increase the efficiency of the NBAS operations, allowing for processing of multiple battery packs per unit of time in a used battery depot. The method ends at step 1520.

One advantage of the method 1500 and the described NBAS is the ability to perform SOH, and RUL assessment in situ, as opposed to having to place the battery or battery cells in purpose-built stations, or chambers. Some of these industrial chambers can be expensive or impractical, particularly for larger batteries, such as those used in EVs and HEVs.

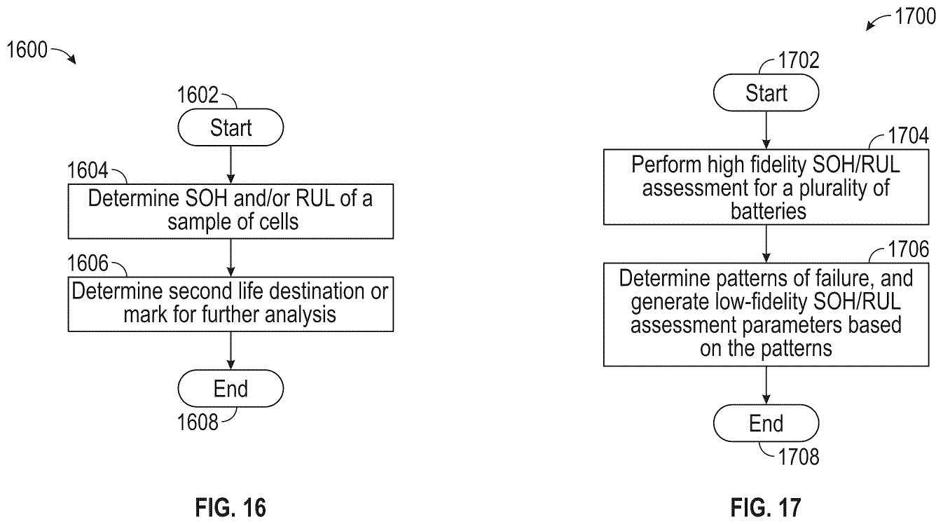

FIG. 16 illustrates a flowchart of an example method 1600 of performing battery health assessment, using a selection or a sample of the cells of a battery. Many secondary batteries, including EV and HEV batteries can include multiple modules, and hundreds or thousands of cells. Traditional charge, and discharge techniques for assessing SOH can take substantial amount of time. For example, for some EV batteries, each charge and discharge cycle can take in excess of 12 hours, and multiple charge, and discharge cycles may be needed to assess the SOH of a battery. The described embodiments include performing the method 1500, or a portion thereof, for a selection of the cells in a battery pack and making a determination of the SOH and/or the RUL of the entire battery pack from the SOH and/or RUL of a sample of the cells.

The method starts at step 1602. At step 1604, the method 1500, or a portion thereof, can be performed for a selection of the cells in the battery pack. In some embodiments, the selection can be made randomly. In other embodiments, the selection of the cells can be based on prior observed failure patterns in a particular battery type. At step 1606, a second life decision for the entire battery pack can be made on the basis of the outcome of SOH, and/or RUL assessment of the selection of the cells. For example, for some battery packs, a detection of failure among a sample size beyond a threshold may indicate that further disassembly of the battery is not economical. That determination can, in turn, help render a second life decision, such as “the battery should be forwarded to a recycling plant as opposed to being disassembled and repaired for reusing, or repurposing.” Step 1606 can also include marking or flagging a battery pack for further or more comprehensive SOH/RUL analysis. In this manner, the methods 1500, and 1600 can be used as a triaging method when a processing plant, such as a used battery depot receives a substantial number of batteries on a rolling basis. The method ends at step 1608.

### Low- and High-Fidelity Battery Health Assessment

High-fidelity or comprehensive SOH/RUL analysis, where every cell, or a substantial portion of the cells are assessed for SOH and/or RUL, can provide an accurate basis for making a second life decision for the battery. However, the high-fidelity, or comprehensive approaches can be too time-consuming or impractical to employ when a substantial number of battery packs are to be processed in a used battery depot, and routed to a second life destination. Nevertheless, high-fidelity comprehensive approaches can provide training data and clues for effective sampling when performing low-fidelity assessment.

FIG. 17 illustrates a flowchart of an example method 1700, for using high-fidelity battery assessment to obtain parameters for performing low-fidelity assessment. The method starts at step 1702. At step 1704, high-fidelity SOH/RUL assessment can be performed for a plurality of batteries of the same type. Electrical charge and discharge methods, as well as the method 1500, or a portion thereof, can be used to perform the high-fidelity assessments. At step 1706, various AI or non-AI techniques can be used to determine patterns of failure in a battery type. Such patterns of failures can be correlated or used to determine sample size, sample cell positions, scan order, and other parameters of low-fidelity assessment. For example, by performing high-fidelity assessments for multiple batteries of the same type, common failure and degradation points and pathways can be identified. When performing low-fidelity assessment, the sample cells can be selected in and/or near the identified failure points and pathways. In some embodiments, unsupervised AI techniques applied to the results of the high-fidelity assessments can be used to determine the likely failure sites in a battery type. Based on the structural data 1208 of the battery, a sample size around the likely failure sites can be identified, and used in low-fidelity assessments. Example unsupervised techniques that can be applied to the results of high-fidelity assessments can include, k-means clustering, k-nearest neighbors (KNN), hierarchal clustering, anomaly detection, unsupervised techniques using neural networks, principal component analysis, independent component analysis, Apriori algorithm, and others.

The high-fidelity analysis can be used to generate a low-fidelity assessment model for each battery type, where the model can include sampling parameters, such as location, number, scan order and other parameters. Furthermore, when the low-fidelity assessment model is deployed in a used battery depot, where a substantial number of used batteries are assessed by the model, the results can be used to update the model iteratively, to improve the effectiveness and accuracy of the sampling parameters. For example, the positional distributions of cell failures within a battery pack model can indicate a candidate pathway for scanning and the order of scanning of the cells in a pack. The distribution and frequency of failures can also indicate a threshold number of faults, beyond which the battery can be deemed unsalvageable. Alternatively, the low-fidelity assessment model can include a parameter indicating a number of randomly sampled healthy cells, which if detected, the battery can be tagged as a candidate for reusing or repurposing.

### SOH Versus RUL Assessment

State of health (SOH) is a parameter or a collection of parameters that can be derived from various measured parameters of a battery at any given time. In other words, SOH is a snapshot in time of the condition of a battery. Remaining useful life (RUL) of a battery, on the other hand, is a prediction of the condition of the battery in the future. While SOH is related to the RUL, it is not always a reliable indicator of future life of a battery. For example, in some instances, the SOH of a battery might be within specification, but the battery might be only a few cycles away from a failure. RUL can be highly non-linear and difficult to measure or predict. However, a facility, such as a used battery depot, can have access to, and can observe and record, the health and useful life profile of a substantial number of batteries. The historical record of a substantial number of batteries over time can be used to build a model that can accurately, or relatively accurately, predict, not only the present SOH of a battery, but also its future RUL. In this regard both traditional electrical testing (charging and discharging of the cells) and non-intrusive testing can enrich the models that predict SOH and RUL of a battery.

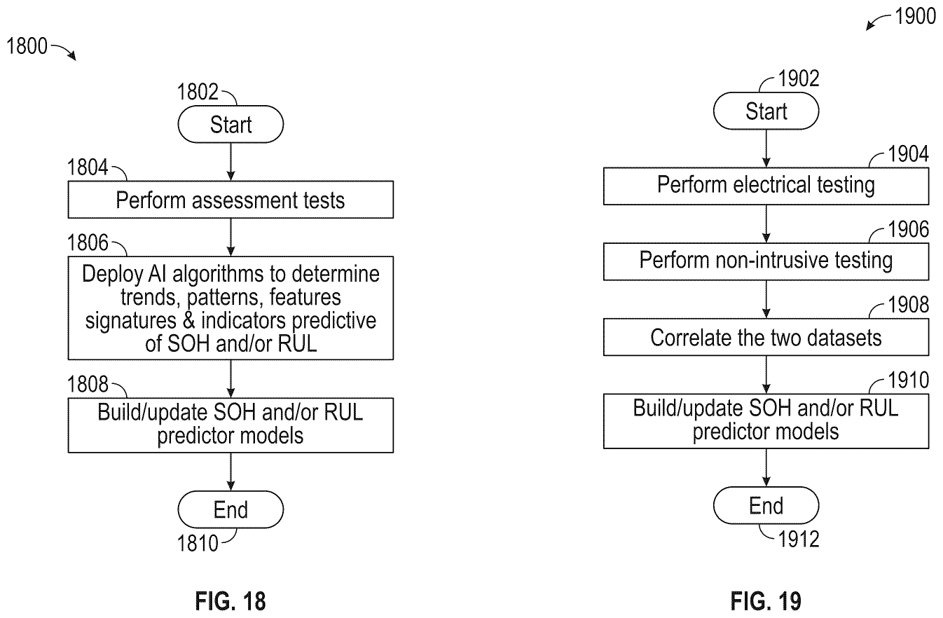

FIG. 18 illustrates a flowchart of an example method 1800 for building one or more SOH and RUL prediction models. The method starts at step 1802. At step 1804, a plurality of battery assessment tests can be performed. These can include electrical and non-intrusive tests on a type of battery. Methods such as charging and discharging, the method 1500, or a portion thereof, CT scanning, X-ray and any assessment test method can be performed to build a dataset of battery health profiles. Furthermore, the tests can be performed for the same battery type at different stages of the batteries' lives. For example, a used battery depot, can receive numerous copies of a battery type of different ages, over the duration of the operation of depot. By performing assessment tests, over time, the test data illustrates trends, signatures, and patterns, predictive of future SOH, or RUL of that battery type. At step 1806, various supervised or unsupervised AI techniques can be used to detect trends, patterns, features, signatures and indicators, predictive of the future SOH, or RUL of a type of battery. At step 1808, the output of step 1806 can be used to build one or more SOH and RUL predictor models. The method ends at step 1810.

### Non-Intrusive Testing Versus Electrical Testing

Non-intrusive testing includes transmitting a signal through a battery or a portion of a battery, for example a battery cell, or a selection of the battery cells, and detecting a reflection of the signal. Non-intrusive test results can be mapped and/or processed by a variety of techniques. However, non-intrusive test results, do not include any electrical measurement or parameters that are typically considered directly in SOH assessment. The non-intrusive test results, do, however, contain information about the physical structure of the battery or the cells. The physical structure of the battery or the cells, of course, are related to the present and future state of health of the battery or the cells. As such, correlating a dataset of non-intrusive test results to electrical parameters of SOH, can yield better predictions for SOH and RUL.

FIG. 19 illustrates a flowchart of an example method 1900 of building a SOH and/or RUL model by correlating the results of non-intrusive tests with electrical testing. The method starts at step 1902. At steps 1904, and 1906, electrical and non-intrusive testing are performed, respectively. At step 1908, the test datasets from steps 1904, 1906 are correlated or mapped. In this manner, the electrical profile of a battery can be mapped to its structural profile, obtained from non-intrusive testing. Steps 1904-1908 can be performed for batteries whose conditions are unknown or can also be performed for batteries whose conditions are known. For example, the method 1900 can be performed on batteries, which are aged artificially by performing repeated charge, discharge cycles. In this manner, a pairing of structural profile and electrical profile for that type of battery at a selected age can be obtained. Similarly, various defects can be induced in one or more batteries, by performing high current charge, high current discharge, and/or other techniques, simulating the real-world circumstances that can cause damage to a battery. Alternatively, batteries that have a known damage can be procured.

Performing the method 1900 can yield a database of pairings of the electrical and structural profiles of a battery for various types of degradation or damage. At step 1910, the pairings from the correlations obtained at step 1908 can be used to build and/or to update one or more SOH and/or RUL predictor models. For example, the model can be used to efficiently determine and/or predict an electrical profile of a battery, its age and/or damage type by detecting a match between the exhibited structural profile of the battery, obtained by performing non-intrusive testing, and a recorded structural profile, obtained previously by performing steps 1904-1908. The models can perform inference operations, by detecting or matching a structural profile of a battery to a structural profile for which there is a previously recorded electrical profile. The previously recorded electrical profile can be assigned to the battery. The method ends at step 1912.

### Heatmap

In some embodiments, the various described methods and models can be used to scan all cells of a battery and generate a heatmap of the health of the cells. Heatmaps can be a visual representation of the SOH of a battery an. They can be used to determine a secondary life destination for the battery, such as reusing, repurposing or recycling. Heatmaps, obtained through the described embodiments, can be more useful in representing the SOH and/or RUL of a battery, compared to the single SOH parameters, obtained using traditional SOH assessment methods since they contain more granular SOH or RUL data, including for example, SOH or RUL data at the cell level. By contrast, some traditional methods, only provide pack-level SOH data.

### Hardware

In some embodiments, separate dismantling systems and dedicated cell-evaluation setups can be implemented in or in combination with the described ABDS. Disassembly robotic agents can extract cells from a battery pack, and can place them in an assessment system, armed with different robotic agents. In other embodiments, the cells need not be extracted, and the expense of having a separate assessment system can be spared, as robotic agents, armed with non-intrusive sensors can perform assessment tests in situ. If a determination of worthiness of disassembly is reached, based on SOH and/or RUL of the cell, the ABDS can proceed with the autonomous disassembly of the battery.

In some embodiments, one or more work stations 108 can include conformal features designed to increase or maximize contact between non-intrusive sensors and the relevant surfaces.

In some embodiments, the non-intrusive sensors can be coupled to the robotic agents 104 that include or are capable of also coupling with one or more disassembly tools. For example, the non-intrusive test sensors can be implemented in probes, concentric to boring/coring cutting bits.

In scenarios, where partial disassembly is performed to provide access to the cells and contact to the non-intrusive sensors, the ABDS robotic agents can perform precise or near-precise cuts above or below the target cell. The robotic agents can also peel covers back, and/or remove material to provide or increase access.

In other scenarios, no disassembly is performed, and the non-intrusive sensors can perform their functions from outside the battery pack.

robotic agents can execute motion trajectories, moving non-intrusive sensors and tools to target portions of the battery, reducing manual labor, and improving precision and safety of the disassembly and/or assessment operations.

### Examples

It will be appreciated that the present disclosure may include any one and up to all of the following examples.

Example 1: A method comprising: identifying a battery pack; retrieving battery pack data; detecting cell locations from the battery pack data; generating one or more motion trajectories, each motion trajectory comprising a movement path for a robotic agent, coupled with a non-intrusive sensor, to move from an initial location to a target cell location; executing the motion trajectories, comprising the robotic agent moving the non-intrusive sensor to the target cell;

performing non-intrusive test and collecting non-intrusive test data, comprising transmitting a signal through the target cell and receiving a reflection of the signal; correlating the non-intrusive test data to one or more state of health (SOH) and/or remaining useful life (RUL) of the battery; and determining a state of health (SOH) and/or a remaining useful life (RUL) of the battery, based at least in part on the correlation and the non-intrusive test data.

Example 2: The method of Example 1, further comprising: determining a secondary life destination for the battery, at least in part based on the SOH and/or the RUL.

Example 3: The method of some or all of Examples 1 and 2, wherein the non-intrusive sensors comprise one or more ultrasonic sensors, one or more computed tomography (CT) sensors, or one or more X-ray sensors.

Example 4: The method of some or all of Examples 1-3, wherein the non-intrusive test is performed on a sample of the cells in the battery pack.

Example 5: The method of some or all of Examples 1-4, further comprising: performing high-fidelity health assessment for a plurality of batteries of a single type; determining patterns and pathways of failure, comprising cell locations on the plurality of the batteries likely to experience failure; and generating parameters for low-fidelity health assessment, based at least in part on the determined patterns and pathways, wherein the parameters comprise cell locations, and number of cells likely to experience failure.

Example 6: The method of some or all of Examples 1-5, further comprising: inducing a defect in a test battery and/or one or more cells of a test battery; performing the non-intrusive test on the test battery and/or the test battery cells, collecting training test data; and training an artificial intelligence model with the training test data, wherein the trained artificial intelligence model receives an output of the non-intrusive test sensors and identifies patterns of the defect in the output, wherein determining the SOH and/or the RUL of the battery is at least in part, based on performing inference operations by the trained artificial intelligence model on the collected test data.

Example 7: The method of some or all of Examples 1-6, further comprising: generating a heatmap of the SOH and/or the RUL of the battery cells, based at least in part, on the determined SOH and/or RUL.

Example 8: The method of some or all of Examples 1-7, further comprising: performing autonomous disassembly of the battery, based at least in part on the SOH, and/or RUL.

Example 9: The method of some or all of Examples 1-8, further comprising: detecting battery failure patterns from a plurality of SOH and/or RULs obtained from a plurality of batteries; and performing the non-intrusive test on a sample of the cells in the battery, wherein the sample of cells are determined at least in part based on the failure patterns.

Example 10: The method of some or all of Examples 1-9, further comprising: performing electrical battery health assessment tests on a plurality of batteries of a single type; generating an electrical profile dataset of the batteries, based at least in part on the electrical health assessment test results; performing non-intrusive health assessment tests on the plurality of the batteries; generating a structural profile dataset of the batteries, based at least in part on the non-intrusive health assessment test results; correlating the electrical profile dataset and the structural profile dataset, by generating a health predictor model, comprising matching electrical profiles and structural profiles; performing non-intrusive tests on an incoming battery of the single type; generating a structural profile of the incoming battery, based at least in part on results of the non-intrusive tests; using the health predictor model, identifying a matching electrical profile to the structural profile of the incoming battery; and generating a prediction of state of health and/or remaining useful life of the incoming battery, based at least in part on the matching electrical profile.

Example 11: A non-transitory computer storage that stores executable program instructions that, when executed by one or more computing devices, configure the one or more computing devices to perform or cause to perform operations comprising: identifying a battery pack; retrieving battery pack data; detecting cell locations from the battery pack data; generating one or more motion trajectories, each motion trajectory comprising a movement path for a robotic agent, coupled with a non-intrusive sensor, to move from an initial location to a target cell location; executing the motion trajectories, comprising the robotic agent moving the non-intrusive sensor to the target cell; performing non-intrusive test and collecting non-intrusive test data, comprising transmitting a signal through the target cell and receiving a reflection of the signal; correlating the non-intrusive test data to one or more state of health (SOH) and/or remaining useful life (RUL) of the battery; and determining a state of health (SOH) and/or a remaining useful life (RUL) of the battery, based at least in part on the correlation and the non-intrusive test data.

Example 12: The non-transitory computer storage of Example 11, wherein the operations further comprise: determining a secondary life destination for the battery, at least in part based on the SOH and/or the RUL.

Example 13: The non-transitory computer-storage of some or all of Examples 11 and 12, wherein the non-intrusive sensors comprise one or more ultrasonic sensors, one or more computed tomography (CT) sensors, or one or more X-ray sensors.

Example 14: The non-transitory computer-storage of some or all of Examples 11-13, wherein the non-intrusive test is performed on a sample of the cells in the battery pack.

Example 15: The non-transitory computer storage of some or all of Examples 11-14, wherein the operations further comprise: performing high-fidelity health assessment for a plurality of batteries of a single type; determining patterns and pathways of failure, comprising cell locations on the plurality of the batteries likely to experience failure; and generating parameters for low-fidelity health assessment, based at least in part on the determined patterns and pathways, wherein the parameters comprise cell locations, and number of cells likely to experience failure.

Example 16: The non-transitory computer storage of some or all of Examples 11-15, wherein the operations further comprise: inducing a defect in a test battery and/or one or more cells of a test battery; performing the non-intrusive test on the test battery and/or the test battery cells, collecting training test data; and training an artificial intelligence model with the training test data, wherein the trained artificial intelligence model receives an output of the non-intrusive test sensors and identifies patterns of the defect in the output, wherein determining the SOH and/or the RUL of the battery is at least in part, based on performing inference operations by the trained artificial intelligence model on the collected test data.

Example 17: The non-transitory computer storage of some or all of Examples 11-16, wherein the operations further comprise: generating a heatmap of the SOH and/or the RUL of the battery cells, based at least in part, on the determined SOH and/or RUL.

Example 18: The non-transitory computer storage of some or all of Examples 11-17, wherein the operations further comprise: performing autonomous disassembly of the battery, based at least in part on the SOH, and/or RUL.

Example 19: The non-transitory computer storage of some or all of Examples 11-18, wherein the operations further comprise: detecting battery failure patterns from a plurality of SOH and/or RULs obtained from a plurality of batteries; and performing the non-intrusive test on a sample of the cells in the battery, wherein the sample of cells are determined at least in part based on the failure patterns.

Example 20: The non-transitory computer storage of some or all of Examples 11-19, wherein the operations further comprise: performing electrical battery health assessment tests on a plurality of batteries of a single type; generating an electrical profile dataset of the batteries, based at least in part on the electrical health assessment test results; performing non-intrusive health assessment tests on the plurality of the batteries; generating a structural profile dataset of the batteries, based at least in part on the non-intrusive health assessment test results; correlating the electrical profile dataset and the structural profile dataset, by generating a health predictor model, comprising matching electrical profiles and structural profiles; performing non-intrusive tests on an incoming battery of the single type; generating a structural profile of the incoming battery, based at least in part on results of the non-intrusive tests; using the health predictor model, identifying a matching electrical profile to the structural profile of the incoming battery; and generating a prediction of state of health and/or remaining useful life of the incoming battery, based at least in part on the matching electrical profile.

While the invention has been particularly shown and described with reference to specific embodiments thereof, it should be understood that changes in the form and details of the disclosed embodiments may be made without departing from the scope of the invention. Although various advantages, aspects, and objects of the present invention have been discussed herein with reference to various embodiments, it will be understood that the scope of the invention should not be limited by reference to such advantages, aspects, and objects. Rather, the scope of the invention should be determined with reference to patent claims.

What is claimed is:

1. A method comprising:
identifying a battery pack;
retrieving battery pack data;
detecting cell locations from the battery pack data;
generating one or more motion trajectories, each motion trajectory comprising a movement path for a robotic agent, coupled with a non-intrusive sensor, to move from an initial location to a target cell location;
executing the motion trajectories, comprising the robotic agent moving the non-intrusive sensor to the target cell;
performing non-intrusive test and collecting non-intrusive test data, comprising transmitting a signal through the target cell and receiving a reflection of the signal;
correlating the non-intrusive test data to one or more state of health (SOH) and/or remaining useful life (RUL) of the battery; and
determining a state of health (SOH) and/or a remaining useful life (RUL) of the battery, based at least in part on the correlation and the non-intrusive test data.

2. The method of claim 1, further comprising: determining a secondary life destination for the battery, at least in part based on the SOH and/or the RUL.

3. The method of claim 1, wherein the non-intrusive sensors comprise one or more ultrasonic sensors, one or more computed tomography (CT) sensors, or one or more X-ray sensors.

4. The method of claim 1, wherein the non-intrusive test is performed on a sample of the cells in the battery pack.

5. The method of claim 1, further comprising:
performing high-fidelity health assessment for a plurality of batteries of a single type;
determining patterns and pathways of failure, comprising cell locations on the plurality of the batteries likely to experience failure; and
generating parameters for low-fidelity health assessment, based at least in part on the determined patterns and pathways, wherein the parameters comprise cell locations, and number of cells likely to experience failure.

6. The method of claim 1, further comprising:
inducing a defect in a test battery and/or one or more cells of a test battery;
performing the non-intrusive test on the test battery and/or the test battery cells, collecting training test data; and
training an artificial intelligence model with the training test data, wherein the trained artificial intelligence model receives an output of the non-intrusive test sensors and identifies patterns of the defect in the output,
wherein determining the SOH and/or the RUL of the battery is at least in part, based on performing inference operations by the trained artificial intelligence model on the collected test data.

7. The method of claim 1, further comprising: generating a heatmap of the SOH and/or the RUL of the battery cells, based at least in part, on the determined SOH and/or RUL.

8. The method of claim 1, further comprising: performing autonomous disassembly of the battery, based at least in part on the SOH, and/or RUL.

9. The method of claim 1, further comprising:
detecting battery failure patterns from a plurality of SOH and/or RULs obtained from a plurality of batteries; and
performing the non-intrusive test on a sample of the cells in the battery, wherein the sample of cells are determined at least in part based on the failure patterns.

10. The method of claim 1, further comprising:
performing electrical battery health assessment tests on a plurality of batteries of a single type;
generating an electrical profile dataset of the batteries, based at least in part on the electrical health assessment test results;
performing non-intrusive health assessment tests on the plurality of the batteries;
generating a structural profile dataset of the batteries, based at least in part on the non-intrusive health assessment test results;
correlating the electrical profile dataset and the structural profile dataset, by generating a health predictor model, comprising matching electrical profiles and structural profiles;
performing non-intrusive tests on an incoming battery of the single type;
generating a structural profile of the incoming battery, based at least in part on results of the non-intrusive tests;
using the health predictor model, identifying a matching electrical profile to the structural profile of the incoming battery; and
generating a prediction of state of health and/or remaining useful life of the incoming battery, based at least in part on the matching electrical profile.

11. A non-transitory computer storage that stores executable program instructions that, when executed by one or more computing devices, configure the one or more computing devices to perform or cause to perform operations comprising:
identifying a battery pack;
retrieving battery pack data;
detecting cell locations from the battery pack data;
generating one or more motion trajectories, each motion trajectory comprising a movement path for a robotic agent, coupled with a non-intrusive sensor, to move from an initial location to a target cell location;
executing the motion trajectories, comprising the robotic agent moving the non-intrusive sensor to the target cell;
performing non-intrusive test and collecting non-intrusive test data, comprising transmitting a signal through the target cell and receiving a reflection of the signal;
correlating the non-intrusive test data to one or more state of health (SOH) and/or remaining useful life (RUL) of the battery; and
determining a state of health (SOH) and/or a remaining useful life (RUL) of the battery, based at least in part on the correlation and the non-intrusive test data.

12. The non-transitory computer storage of claim 11, wherein the operations further comprise: determining a secondary life destination for the battery, at least in part based on the SOH and/or the RUL.

13. The non-transitory computer-storage of claim 11, wherein the non-intrusive sensors comprise one or more ultrasonic sensors, one or more computed tomography (CT) sensors, or one or more X-ray sensors.

14. The non-transitory computer-storage of claim 11, wherein the non-intrusive test is performed on a sample of the cells in the battery pack.

15. The non-transitory computer storage of claim 11, wherein the operations further comprise:
performing high-fidelity health assessment for a plurality of batteries of a single type;
determining patterns and pathways of failure, comprising cell locations on the plurality of the batteries likely to experience failure; and
generating parameters for low-fidelity health assessment, based at least in part on the determined patterns and pathways, wherein the parameters comprise cell locations, and number of cells likely to experience failure.

16. The non-transitory computer storage of claim 11, wherein the operations further comprise:
inducing a defect in a test battery and/or one or more cells of a test battery;
performing the non-intrusive test on the test battery and/or the test battery cells, collecting training test data; and
training an artificial intelligence model with the training test data, wherein the trained artificial intelligence model receives an output of the non-intrusive test sensors and identifies patterns of the defect in the output,
wherein determining the SOH and/or the RUL of the battery is at least in part, based on performing inference operations by the trained artificial intelligence model on the collected test data.

17. The non-transitory computer storage of claim 11, wherein the operations further comprise: generating a heatmap of the SOH and/or the RUL of the battery cells, based at least in part, on the determined SOH and/or RUL.

18. The non-transitory computer storage of claim 11, wherein the operations further comprise: performing autonomous disassembly of the battery, based at least in part on the SOH, and/or RUL.

19. The non-transitory computer storage of claim 11, wherein the operations further comprise:
detecting battery failure patterns from a plurality of SOH and/or RULs obtained from a plurality of batteries; and
performing the non-intrusive test on a sample of the cells in the battery, wherein the sample of cells are determined at least in part based on the failure patterns.

20. The non-transitory computer storage of claim 11, wherein the operations further comprise:
performing electrical battery health assessment tests on a plurality of batteries of a single type;
generating an electrical profile dataset of the batteries, based at least in part on the electrical health assessment test results;
performing non-intrusive health assessment tests on the plurality of the batteries;
generating a structural profile dataset of the batteries, based at least in part on the non-intrusive health assessment test results;
correlating the electrical profile dataset and the structural profile dataset, by generating a health predictor model, comprising matching electrical profiles and structural profiles;
performing non-intrusive tests on an incoming battery of the single type;
generating a structural profile of the incoming battery, based at least in part on results of the non-intrusive tests;
using the health predictor model, identifying a matching electrical profile to the structural profile of the incoming battery; and
generating a prediction of state of health and/or remaining useful life of the incoming battery, based at least in part on the matching electrical profile.
